(19) United States
(12) Patent Application Publication
(10) Pub. No.: US 2026/0009847 A1
(43) Pub. Date: Jan. 8, 2026

(54) LOW-POWER SCAN-BASED TESTING FOR INTEGRATED CIRCUIT DEVICES

(71) Applicant: TEXAS INSTRUMENTS INCORPORATED, DALLAS, TX (US)

(72) Inventors: MUDASIR KAWOOSA, BANGALORE (IN); SIDDHARTH SARIN, Bangalore (IN); SOMALATHA T, Thanjavur (IN); VARUN ITHAL, Thirthahalli (IN); GOKUL SABADA, Bangalore (IN); BADARISH MOHAN SUBBANNAVAR, Bangalore (IN)

(21) Appl. No.: 19/219,558

(22) Filed: May 27, 2025

(30) Foreign Application Priority Data
Jul. 5, 2024 (IN) 202441051794

(51) Int. Cl. G01R 31/317; G01R 31/28; G01R 31/3185

(52) U.S. Cl. CPC G01R 31/31724; G01R 31/2834; G01R 31/318544

(57) ABSTRACT

In an example, a flip-flop (FF) circuit includes a data output terminal and data selection logic that can be configured to output one of a scan data input signal or a functional data input signal as a selected data signal based on a scan enable signal. The FF circuit further includes a data storage circuit that can be configured to capture and store a logic value represented by the selected data signal as a stored logical value. The FF circuit further includes output gating logic that can be coupled to the data output terminal and is configured to generate a data output signal at the data output terminal based on the stored logical value during a capture phase of a scan mode of operation. During a scan shift phase of the scan mode of operation, the output gating logic suppresses the data output signal at the data output terminal.

### TECHNICAL FIELD

This disclosure relates to scan-based testing of integrated circuit (IC) devices. More specifically, this disclosure relates to low-power scan-based testing for IC devices.

### BACKGROUND

Scan-based testing, in context of design-for-test (DFT), is a technique used for verifying the defect in a chip or integrated circuit (IC) device during or after fabrication. In scan-based testing, a scan chain circuit, including a series of flip-flop (FF) circuits, operates as a shift register to load test patterns (test vectors) into the IC device and capture output responses from functional logic, such as combinational logic, sequential logic, or memory elements. These test patterns stimulate the functional logic to detect manufacturing defects (e.g., stuck-at faults, bridging faults) or design errors (e.g., timing violations).

### SUMMARY

A first example relates to a flip-flop (FF) circuit that includes a data output terminal and data selection logic that can be configured to receive a scan enable signal, a scan data input signal and a functional data input signal and configured to output one of the scan data input signal or the functional data input signal as a selected data signal based on the scan enable signal. The FF circuit further includes a data storage circuit that can be coupled to the data selection logic and configured to capture and store a logic value represented by the selected data signal as a stored logical value. The FF circuit further includes output gating logic that can be coupled to the data output terminal and the data storage circuit. The output gating logic can be configured to generate a data output signal at the data output terminal based on the stored logical value during a capture phase of a scan mode of operation. During a scan shift phase of the scan mode of operation, the output gating logic suppresses the data output signal at the data output terminal.

A second example relates to a system that includes an integrated circuit (IC) device that can include a scan chain circuit that includes a plurality of flip-flop (FF) circuits. At least one FF circuit of the plurality of FF circuits includes a data output terminal and data selection logic that can be configured to receive a scan enable signal, a scan data input signal and a functional data input signal and configured to output one of the scan data input signal or the functional data input signal as a selected data signal based on the scan enable signal. The at least one FF circuit further includes a data storage circuit that can be coupled to the data selection logic and configured to capture and store a logic value represented by the selected data signal as a stored logical value. The at least one FF circuit further includes output gating logic that can be coupled to the data output terminal and the data storage circuit. The output gating logic can be configured to generate a data output signal at the data output terminal based on the stored logical value during a capture phase of a scan mode of operation. During a scan shift phase of the scan mode of operation, the output gating logic suppresses the data output signal at the data output terminal.

A third example relates to an FF circuit that can include a plurality of terminal that can include a scan data (SD) input terminal, a data output terminal, a scan enable (SE) input terminal and a clock input terminal. The FF circuit further includes data selection logic that can have a first input that can be coupled to the SD input terminal, a second input that can be coupled to the SE input terminal and an output. The FF circuit further includes a data storage circuit that can have a first input that can be coupled to the output of the data selection logic, a second input that can be coupled to the clock input terminal and an output. The FF circuit further includes output gating logic that can have a first input that can be coupled to the output of the data storage circuit, a second input that can be coupled to the SE input terminal and an output coupled to the data output terminal.

### BRIEF DESCRIPTION OF THE DRAWINGS

FIG. 1 is an example of a block diagram of a chip testing system.

FIG. 2 is an example of a block diagram of a scan chain circuit.

FIG. 3 is an example of a block diagram of an OR-gated scan FF circuit.

FIG. 4 is an example of a block diagram of an AND-gated scan FF circuit.

FIG. 5 is an example of a block diagram of another OR-gated scan FF circuit.

FIG. 6 is an example of a block diagram of another AND-gated scan FF circuit.

FIG. 7 is an example of a comparative analysis of a current-resistance (IR) drop observed during scan-based testing in an integrated circuit (IC) device.

FIG. 8 is an example of a block diagram of a chip.

### DETAILED DESCRIPTION

This disclosure relates to scan-based testing of integrated circuit (IC) devices, such as systems-on-chip (SoCs), microprocessors, microcontrollers, or application-specific integrated circuits (ASICs) and more particularly to reducing power consumption and mitigating voltage drops across resistive interconnects during a scan shift phase. An IC device includes functional logic, such as combinational logic (e.g., AND, OR, or NAND gates, etc.), sequential logic and/or memory elements (volatile and non-volatile), analog components and a scan chain circuit that includes flip-flop (FF) circuits interconnected to form a scan chain. The scan chain operates as a shift register structure wherein a scan output of one FF circuit is coupled to a scan input of a subsequent FF circuit, enabling serial shifting of test vectors during scan-based testing. During this shifting, data output terminals of the FF circuits, which are coupled to downstream combinational logic, exhibit frequent state changes (e.g., logic 0 to 1 or 1 to 0) as test vectors propagate through the scan chain, thereby increasing a switching activity of the IC. In the scan shift phase, the scan chain circuit serially shifts test vectors, sequences of logic values (e.g., 0s and 1s), through the scan chain. This shifting elevates a switching activity of the IC due to a rapid, clock-driven propagation of test vectors, wherein each FF circuit captures a new logic value from a preceding FF circuit's scan output and updates an internal state on each clock cycle. This process causes frequent state changes at the data output terminals of the FF circuits, as the shifting test vectors produce a high rate of logic transitions compared to a functional operation of the IC device.

In functional operation, the IC device processes application-specific data, wherein data states at the data output terminals of the FF circuits toggle at a slower rate, driven by less frequent and more predictable logic operations dictated by the IC device's application. The elevated switching activity in the scan shift phase results from simultaneous toggling of multiple FF circuits as test vectors propagate through the scan chain, driving downstream combinational logic and inducing frequent signal transitions. These elevated transitions at the data output terminals of the FF circuits cause a voltage drop, referred to as IR drop, across resistive interconnects (e.g., conductive paths, such as metal traces or vias) within a power distribution network of the IC device that connect power supply rails to circuit elements. This voltage drop is localized and thus occurs at one or more specific regions of the power distribution network near the FF circuits and combinational logic exhibiting high switching activity, rather than uniformly impacting an entire IC device. The IR drop, a voltage reduction, is amplified by increased current flow through these resistive interconnects, particularly in the power distribution network supplying the FF circuits and combinational logic.

IR drop can lead to timing violations in signal propagation, noise on the power supply rail of the IC device and scan test failures due to incorrect logic states or reduced voltage margins. To reduce switching activity at the data output terminals of the FF circuits, which impacts power consumption and IR drop in the downstream combinational logic, scan test optimization techniques, such as multi-mode segmented scan, low-power scan gating, clock staggering and software-based automatic test pattern generation (ATPG) tools, can be employed, but these techniques have trade-offs. For example, multi-mode segmented scan partitions the scan chain into segments to limit simultaneous switching, but requires additional control logic, thereby increasing the chip area dedicated to scan test circuitry. Clock staggering offsets clock signals to FF circuits to reduce concurrent toggling, but extends test duration, reducing test throughput by prolonging the time required to complete scan-based testing. These scan test optimization techniques, such as multi-mode segmented scan and clock staggering, rely on iterative value change dump (VCD) analysis to identify and validate IR drop violations, as the complexity of predicting switching activity requires simulation-based verification, consuming substantial hardware engineering resources, such as computational processing power and memory for simulation tools. Furthermore, existing scan test optimization techniques frequently result in conservative designs of the scan chain circuit, incorporating excessive power switches, transistors configured to isolate power domains to limit IR drop, which increases the overall chip area of the IC device.

Examples are described herein that utilize output-gated scan FF circuits within a scan chain circuit for low-power scan test applications, configured to suppress toggling at data output terminals during a scan shift phase based on deterministic settling of functional data input signals received at the scan FF circuits. These circuits, in some examples referred to as self-compensated output-gated FF circuits, are self-compensated because the circuits can dynamically adjust an output behavior based on a scan enable signal and a deterministic settling of input signals, thereby ensuring minimal switching activity without a need for external control logic. Low-power scan test applications refer to scan-based testing optimized to minimize dynamic power consumption and localized IR drop in the scan chain circuit and downstream combinational logic. Compared to conventional FF-based scan chains that employ non-gated scan FF circuits (e.g., standard D-type flip-flops that do not incorporate output gating logic, as described herein), the output-gated scan FF circuits reduce dynamic power consumption and localized IR drop by preventing unnecessary state changes at the data output terminals, which otherwise drive frequent signal transitions in the combinational logic during the scan shift phase. This suppression minimizes current flow through resistive interconnects in the power distribution network, thereby reducing the voltage drop (IR drop) in and around regions near the FF circuits and combinational logic. By maintaining IR drop within permissible limits, such that the voltage reduction does not exceed a threshold relative to the minimum supply voltage required for reliable operation of the IC device, the output-gated scan FF circuits improve test reliability by ensuring accurate logic state capture and reducing the likelihood of scan test failures due to voltage-related errors. Furthermore, utilization of output-gated scan FF circuits within the scan chain circuit, as opposed to conventional non-gated scan FF circuits, reduces the need for iterative VCD analysis. The predictable suppression of toggling simplifies verification of IR drop violations, requiring fewer simulation iterations than conventional scan test optimization techniques and, in some instances, eliminating the need for such analysis entirely. Moreover, by incorporating output-gated scan FF circuits as described herein into the scan chain circuit avoids design area overhead as control logic or power management components needed to meet IR drop during scan shift phase are no longer needed. This incorporation does not result in test time penalties or test coverage loss and is effective across scan test modes, including non-compression modes, where test vectors are applied without data compression and compression modes, where test vectors are compressed to reduce test time and data volume. Additionally, the use of output-gated scan FF circuits is scalable, adaptable to varying IC device sizes and complexities and compatible across electronic design automation (EDA) scan compression methodologies. Thus, the use of output-gated scan FF circuits in a scan chain reduces sequential logic area compared to conventional FF-based scan chains, thereby providing a robust, low-power scan test framework suitable for low-area IC devices, including those deployed in safety-critical applications.

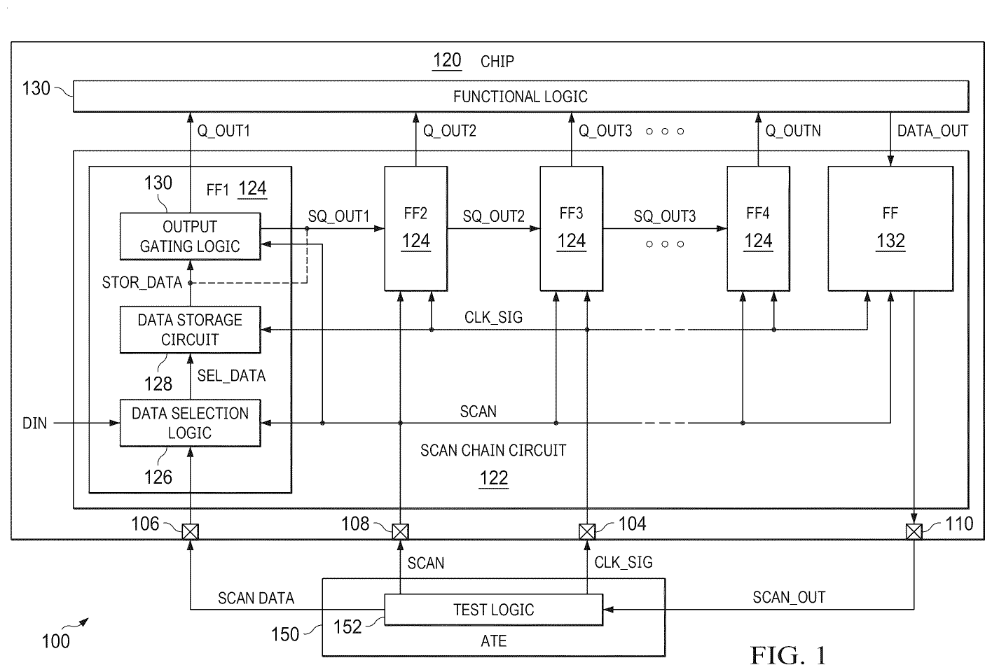

FIG. 1 illustrates an example of a block diagram of a chip testing system 100 (referred to herein for simplicity as “system 100”). The system 100 includes automated test equipment (ATE) 150 with test logic 152. The ATE 150 can be used during or after the fabrication of a chip 120, such as in a testing process referred to as scan-based testing to verify the functionality of combinational logic within the chip 120, such as functional logic 130 of the chip 120. The chip 120 is an integrated circuit (IC) device, which may be, for example, a system-on-chip (SoC), a microprocessor, a microcontroller, or an application-specific integrated circuit (ASIC). In some instances, the chip 120 is a safety-critical device employed in automotive applications. Non-limiting examples of such automotive applications include advanced driver-assistance systems (ADAS) for lane-keeping and adaptive cruise control, electronic control units (ECUs) for engine management and anti-lock braking systems (ABS). The test logic 152, implemented as hardware, firmware, or software within the ATE 150, generates control signals to orchestrate the testing process.

For example, the test logic 152 can provide the chip 120 with test signals including a scan enable signal (identified as “SCAN” in FIG. 1), a scan data signal (identified as “SCAN_DATA” in FIG. 1) and, in some examples, a clock signal (identified as “CLK_SIG” in FIG. 1). In some examples, the test logic 152 instructs the ATE 150 to provide the chip 120 with the test signals. The scan enable signal controls whether the chip 120 operates in a scan mode (for testing) or a functional mode (for normal operation). The scan data signal, in some instances referred to as a test vector, includes a sequence of bits representing one or more test patterns to be loaded into the chip 120 to stimulate the functional logic 130. Stimulation of the functional logic 130 generates output responses that the ATE 150 analyzes to verify the correctness of logic, detecting faults such as stuck-at faults or timing violations. In some examples, the functional logic corresponds to combinational logic and sequential logic. The combinational logic can include logic gates (e.g., AND, OR, XOR and/or NAND gates) arranged to perform one or more functions, such as arithmetic operations, data routing, or control signal generation. While in some examples the scan chain circuit 122 is used to test combinational logic herein, the scan chain circuit 122 (or one or more output-gated scan flip-flop (FF) circuits 124) can also be used in testing other circuit types, such as sequential logic or memory elements, by adapting the test vectors and scan chain configuration. The clock signal synchronizes operations within the chip 120, such as data capture and shifting during scan-based testing. In yet some examples, the ATE 150 generates these signals by interfacing with a test controller or pattern generator within the ATE 150, which interprets instructions from the test logic 152 to produce the appropriate signal sequences. In some examples, the test logic 152 includes the test controller or the pattern generator. In some examples, the clock signal is generated locally by an on-chip clock signal generator, such as a phase-locked loop (PLL) on the chip 120, initiated by a clock control signal from the test logic 152 to ensure precise timing alignment during testing.

For example, the chip 120 includes a clock pin 104, a scan data (SD) pin 106, a scan enable (SE) pin 108 and a scan out (SO) pin 110. The clock pin 104 can be coupled to a clock distribution network within the chip 120 and receive the clock signal, which can originate from the ATE 150 or the on-chip clock generator. Thus, the clock pin 104 can be coupled to an input of a scan chain circuit 122 on the chip 120. The SD pin 106 can be coupled to another input of the scan chain circuit 122 and receives the scan data signal from the ATE 150. The SE pin 108 is coupled to the scan chain circuit 122 and receives the scan enable signal to toggle between scan and functional modes of the chip 120. The SO pin 110 is coupled to an output of the scan chain circuit 122 and provides a scan out signal (identified as “SCAN_OUT” in FIG. 1), which represents test results shifted out from the scan chain circuit 122, to the ATE 150 for analysis. The ATE 150 analyzes the scan out signal by comparing a logical value represented by this signal to an expected test result, generated by simulation or predefined test patterns, to identify discrepancies that indicate manufacturing defects or design errors in the chip 120.

As illustrated in FIG. 1, the chip 120 includes the functional logic 130 and the scan chain circuit 122. The scan chain circuit 122 includes an N number of output-gated scan flip-flop (FF) circuits 124 (identified as “FF1 124,” “FF2 124,” “FF3 124,” “FF4 124,” and “FFN 124” in FIG. 1), where Nis an integer value determined by design considerations of the chip 120, such as a complexity of the functional logic 130 or desired test coverage. In yet some examples, the number of output-gated scan FF circuits 124 is based on the number of sequential elements needed to adequately implement the functional logic 130, as determined through EDA tools during an IC design phase. In some examples, the scan chain circuit 122 can include fewer or more output-gated scan FF circuits 124, depending on functional and test requirements. In yet some examples, not all of the scan FF circuits within the scan chain circuit 122 may be configured as output-gated. Thus, in some examples, at least one scan FF circuit 124 can be output-gated, while others remain ungated, for example, to balance power efficiency and design complexity. An output-gated scan FF circuit refers to an FF circuit that incorporates output gating logic to suppress switching activity at a data output (e.g., data output terminal) during a scan shift phase, thereby reducing power dissipation in functional logic, such as the functional logic 130. An ungated scan FF circuit (or non-gated scan FF circuit), in contrast, lacks such output gating logic and allows a data output to toggle during the scan shift phase. At least some of the output-gated scan FF circuits 124, such as a first output-gated scan FF 124, a second output-gated scan FF 124, a third output-gated scan FF 124 and a fourth output-gated scan FF 124, are connected in a scan chain, forming a shift register structure where a scan output of one FF circuit is coupled to a scan input of the next, enabling serial data shifting during the scan shift phase.

For example, each of the output-gated scan FF circuits 124 receives the clock signal at an input via the clock distribution network on the chip 120. This network can include buffers and/or routing paths so that the clock signal is delivered with minimal skew to synchronize operations across the output-gated scan FF circuits 124. The clock signal triggers data capture or shifting within each of the output-gated scan FF circuits 124, depending on an operational mode of the chip 120. In the scan mode, during a shift phase of the scan mode, the clock signal allows for serial shifting of the test pattern (or test vector) represented by the scan data signal (e.g., a serial data signal) through the scan chain circuit 122. Each output-gated scan FF circuit 124 also receives the scan enable signal at another input. The scan enable signal, when asserted at a logical high, configures each of the output-gated scan FF circuits 124 to operate in the scan mode, enabling loading or unloading of test vectors with respect to the functional logic 130. When de-asserted, the scan enable signal configures each of the output-gated scan FF circuits 124 for functional mode or a capture phase of the scan mode, allowing a respective output-gated scan FF circuit to process functional data.

For example, the first output-gated scan FF circuit 124 (identified as “FF1” in FIG. 1) includes an input to receive the serial scan data signal, which is a test vector provided by the ATE 150 during the scan shift phase of the scan mode of operation of the chip 120. The test vector is received at the SD pin 106 and input to the first output-gated scan FF circuit 124 when the scan enable signal is asserted (e.g., at a logical 1), initiating loading of the test vector into the scan chain circuit 122. The test vector sets an internal state of each output-gated scan FF circuit 124 to a specific logic value of the test vector, where the internal state is the logic value stored at a respective data storage circuit, corresponding to a bit of the test vector. These stored logic values can be used to stimulate the functional logic 130 during testing by providing controlled inputs to verify the functionality of the functional logic 130. The first output-gated scan FF circuit 124 includes data selection logic 126, a data storage circuit 128 and output gating logic 134. One or more remaining output-gated scan FF circuits (identified as “FF2,” “FF3,” “FF4,” and/or “FFN” in FIG. 1) can be configured with a same or similar data selection logic, data storage circuit and/or output gating logic as the first output-gated scan FF circuit 124 as illustrated in FIG. 1.

For example, the data selection logic 126 receives the scan enable signal and a functional data input signal (identified as “DIN” in FIG. 1) at corresponding inputs, which can be provided from upstream logic, such as combinational and/or functional logic, or other circuit elements of the chip 120. Based on the scan enable signal, the data selection logic 126 selects either the scan data signal (during the scan mode) or the functional data input signal (during functional or capture mode) to output as a selected data signal (SEL_DATA) at an output to which an input of the data storage circuit 128 can be coupled. The data selection logic 126 can be implemented using a combination of logic gates, such as AND, OR and/or inverter gates, configured to select (or prioritize) the scan data signal when the scan enable signal is asserted and the functional data input signal when the scan enable signal is de-asserted. In yet some examples, the second, third and fourth output-gated scan FF circuits 124 each include data selection logic that operates in the same or similar manner, selecting either a respective scan data input (e.g., a scan output from the preceding output-gated scan FF circuit t) or a corresponding functional data input signal) based on a state of the scan enable signal. Each of the output-gated scan FF circuits 124 can receive a corresponding functional data input signal from functional logic in the chip 120, which may differ based on the design of the chip 120.

In some examples, the selected data signal is provided to the data storage circuit 128, which captures and stores a logic value of the selected data signal on an edge of the clock signal as a stored logic value. The term “stored logic value” refers to a binary state (0 or 1) latched or captured by the data storage circuit 128, representing either a test vector bit or functional data. The data storage circuit 128 can be implemented as a D-type flip-flop or a similar sequential element, capable of latching a single bit of data. The data storage circuit 128 outputs at an output the stored logic value as a stored data signal (identified as “STOR_DATA” in FIG. 1), to which an input of the output gating logic 134 is coupled. The output gating logic 134 processes the stored data signal and the scan enable signal (or an inverse of the scan enable signal) to produce output signals: a first gated data output signal (identified as “Q_OUT1” in FIG. 1) and a first scan output signal (identified as “SQ_OUT1” in FIG. 1). In some examples, the stored data signal outputted by the data storage circuit 128 corresponds to the first scan output signal. In such examples, an input of the second output-gated scan FF circuit 124 is coupled to the output of the data storage circuit 128 (illustrated with a dashed-line in FIG. 1) to receive the stored data signal as the first scan output signal. The output gating logic 134 can be implemented using logic gates, such as AND, OR and/or NOR gates, with configurations that suppress the gated data output signal to a fixed logic value (e.g., 0 or 1) during the scan shift phase when the scan enable signal is asserted, while allowing the scan output signal to reflect the stored logic value represented by the stored data signal for scan chain operations. This suppression reduces switching activity in the functional logic 130, thereby lowering power consumption.

In some examples, the first gated data output signal is provided to the functional logic 130, representing a functional output of the first output-gated scan FF circuit 124 during the capture phase or functional mode. The first gated data output signal is provided at an output to which a first input of the functional logic 130 is coupled. In some examples, the first scan output signal is provided to an input of a next FF circuit, such as the second output-gated scan FF circuit 124 (identified as “FF2 124” in FIG. 1), enabling serial shifting of test vector bits through the scan chain circuit 122. The first scan output signal is provided at an output of the first output-gated scan FF circuit 124 to which an input of the second output-gated scan FF circuit 124 is coupled. The second output-gated scan FF circuit 124 receives the first scan output signal, which represents the stored logic value from the first output-gated scan FF circuit 124 and, on a next clock edge of the clock signal, captures and stores this value, outputting a second scan output signal (identified as “SQ_OUT2” in FIG. 1) to the third output-gated scan FF circuit 124 (identified as “FF3 124” in FIG. 1). The second scan output signal is provided at an output of the second output-gated scan FF circuit 124 to which an input of the third output-gated scan FF circuit 124 is coupled. The third output-gated scan FF circuit 124 receives the second scan output signal, which represents a stored logic value from the second output-gated scan FF circuit 1124 and, on a next clock edge of the clock signal, captures and stores this value, outputting a third scan output signal (identified as “SQ_OUT3” in FIG. 1) to the fourth output-gated scan FF circuit 124 (identified as “FF4 124” in FIG. 1). Each scan output signal (e.g., SQ_OUT1, SQ_OUT2, SQ_OUT3) is generated based on a stored logic value of a respective FF circuit, which originates from scan data signal or a preceding FF circuit's scan output, propagated through the scan chain during the scan shift phase. This serial shifting process continues through a last output-gated scan FF circuit 124 in the scan chain (e.g., the fourth output-gated scan FF circuit 124 in a scan chain of four FFs), allowing an entire test vector to be loaded into the scan chain circuit 122.

In a non-limiting example, the test vector is “10101” and is loaded into the scan chain circuit 122 using five output-gated scan FF circuits (N=5, with the first output-gated scan FF circuit 124 to the fourth output-gated scan FF circuit 124 in the scan chain). In a first clock cycle of the clock signal, the first output-gated scan FF circuit 124 captures a first bit (1) of the test vector. In a second cycle, the first output-gated scan FF circuit 124 captures a second bit (0) of the test vector and the second output-gated scan FF circuit 124 captures the first bit (1). This continues until, after five cycles, the first output-gated scan FF circuit 124 stores a fifth bit (1) of the test vector, the second output-gated scan FF circuit 124 stores a fourth bit (0) of the test vector, the third output-gated scan FF circuit 124 stores a third bit (1) of the test vector, the fourth output-gated scan FF circuit 124 stores the second bit (0) and the fifth output-gated scan FF circuit 124 stores the first bit (1). Each bit is stored in a data storage circuit of the respective output-gated scan FF circuit 124 and can be referred to as a stored bit or stored test vector bit.

In some examples, during the capture phase, when the scan enable signal is de-asserted, stored test vector bits are applied to the functional logic 130 as respective gated data output signals (e.g., Q_OUT1, Q_OUT2, Q_OUT3, Q_OUT4, etc.). The functional logic 130 processes these input signals and produces an output, which is captured by an output scan FF circuit 132 (identified as “FF 132” in FIG. 1). In some examples, the output scan FF circuit 132 can be implemented as an output-gated scan FF circuit, such as described herein. There can be a Y number of output scan FF circuits 132, where Y is determined by the number of output bits produced by the functional logic 130. For clarity and brevity, a single output scan FF circuit 132 is illustrated in FIG. 1, but there can be Y number of output scan FF circuits based on an output complexity of the functional logic 130. Each output scan FF circuit 132 captures a portion of the functional logic 130 output and provides a scanned out data signal (identified as “SCAN_OUT” in FIG. 1). For example, during a subsequent scan shift phase, when the scan enable signal is asserted, each output scan FF circuit 132 shifts a stored logic value serially through the scan chain circuit 122 to the SO pin 110. The serial shifting process involves each output scan FF circuit 132 outputting a stored logic value, which is passed to the next output scan FF circuit in a scan chain or directly to the SO pin 110, synchronized by one or more clock edges of the clock signal. The functional logic 130 produces a data result signal (identified as “DATA_OUT” in FIG. 1) that represents a processed response to test vector bits applied via the gated data output signals. This data result signal is received at an input of the output scan FF circuit 132, which captures a respective logical value during the capture phase on a clock edge of the clock signal. The captured logical value is then stored in the data storage circuit of the output scan FF circuit 132 and subsequently shifted out as the scanned out data signal (or as part of the scanned out data signal, such as a corresponding bit) during the scan shift phase, enabling the ATE 150 to analyze a response of the functional logic 130.

For example, each output scan FF circuit 132 has an input coupled to a respective output of the functional logic 130, capturing a response to the test vector on a clock edge of the clock signal. While FIG. 1 illustrates a single output scan FF circuit 132, multiple output scan FF circuits 132 may be coupled to the functional logic 130, each capturing a distinct output bit to provide the scanned out data signal to the SO pin 110. For example, with a single output scan FF circuit 132, the captured output is shifted out as the scanned out data signal during a subsequent scan shift phase. With multiple output scan FF circuits 132, each output scan FF circuit captures a distinct output bit and respective stored values are shifted out serially through the scan chain circuit 122 as the scanned out data signal to the SO pin 110.

Upon receiving the scanned out data signal at the ATE 150, the test logic 152 processes the signal to evaluate the functionality of the functional logic 130. The ATE 150 compares a sequence of bits in the scanned out data signal to an expected output pattern, which is predetermined through simulation of the design of the chip 120. Discrepancies between the received scanned out data signal and an expected pattern indicate potential faults, such as manufacturing defects (e.g., stuck-at faults, bridging faults) or design errors (e.g., timing violations). The ATE 150 can log these discrepancies for further analysis, flag the chip 120 as defective, or initiate additional test cycles to isolate the fault. In a non-limiting example, if the scanned out data signal is “01010,” the ATE 150 compares this sequence to an expected output, such as “01010,” which corresponds to a correct response of the functional logic 130 to an applied test vector. If the sequences match, the ATE 150 confirms the functional logic 130 operates correctly for that test case. In other examples, if the scanned out data signal is, for instance, “01110”, a mismatch (e.g., the third bit is 1 instead of 0) indicates a fault, prompting the ATE 150 to record the error and potentially classify the chip 120 as faulty or requiring further diagnostic testing to pinpoint a defect's location or cause.

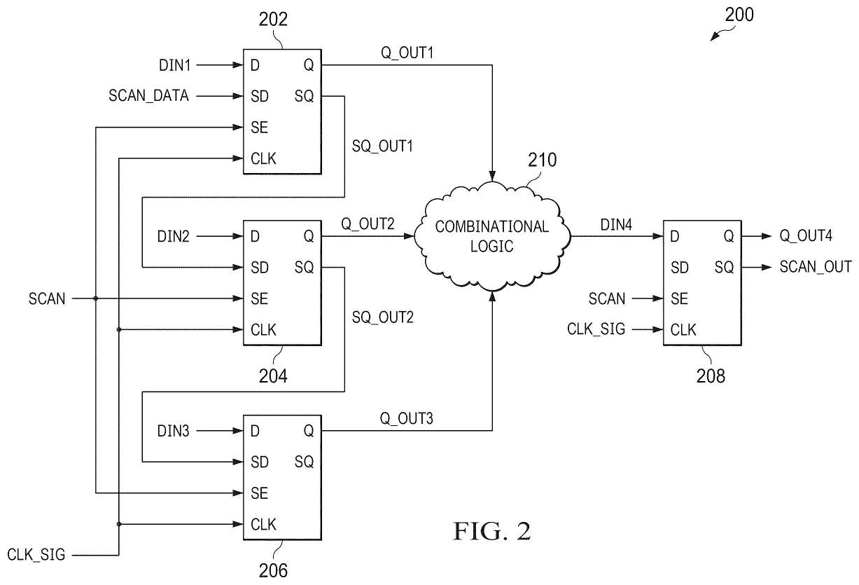

FIG. 2 illustrates an exemplary block diagram of a scan chain circuit 200. The scan chain circuit 200 includes a first FF circuit 202, a second FF circuit 204, a third FF circuit 206 and a fourth FF circuit 208. In some examples, one or more of the FF circuits 202-208 can be referred to as scan chain circuits. In yet some examples, one or more of the FF circuits 202-208 are implemented as output-gated scan FF circuits and thus can correspond to one of the output-gated scan FF circuits 124 of FIG. 1. For example, at least one of the FF circuits 202-208 incorporates output gating logic, such as output gating logic 134 of FIG. 1, to suppress switching activity at a corresponding data output terminal (identified as “Q” in FIG. 2) during a scan shift phase of scan mode. This suppression reduces power dissipation in downstream combinational logic, such as combinational logic 210, by curtailing signal transitions that would otherwise occur during the scan shift phase. During this phase, a scan input sequence is serially shifted through scan chain circuits, such as the FFs circuits 202-206, which can cause frequent toggling at corresponding data output terminals of these FF circuits and trigger switching activity in connected combinational logic, such as the combinational logic 210. The suppression is based on a deterministic settling of a functional data input signal (or data input signal) received at a data input terminal (identified as “D” in FIG. 2) of a respective FF circuit. The term “deterministic settling” refers to a known logical value (e.g., logic 0 or logic 1) expected at a D input terminal of the respective FF circuit during the scan shift phase, which can be determined through analysis of an IC or chip design that includes a scan chain circuit, such as a SoC implementation of the scan chain circuit 200. This analysis can be performed using EDA tools that simulate or statically analyze the IC design to identify settled logic values at data input terminals of scan chain circuits corresponding to one or more of the FF circuits 202-208. For example, the analysis can evaluate upstream combinational logic that drives the D input terminal of each FF circuit to determine a settled logic value when the scan enable signal is asserted at a logical high level. The settled logic value corresponds to a simulated or statically analyzed value that is expected to appear at the D input terminal during the scan shift phase, based on a behavior of the IC design in which the scan chain circuit 200 is implemented (e.g., the chip 120 of FIG. 1). Based on this determined settled value, a corresponding type of output-gated scan FF circuit is selected for use as one or more of the FF circuits 202-208. For example, an AND-gated scan flip-flop circuit is selected when the settled value at the data input terminal is logic 1 and an OR-gated scan flip-flop circuit is selected when the settled value is logic 0.

By way of further example, for the first FF circuit 202, if the upstream combinational logic driving the data input terminal of the first FF circuit 202 (e.g., a NAND gate with inputs tied to outputs of preceding FF circuits) is determined through simulation or static analysis to settle to logic 1 during the scan shift phase, an AND-gated scan flip-flop circuit may be selected to implement the first FF circuit 202. In such an example, the data output terminal of the first FF circuit 202 is gated to logic 0, thereby suppressing unnecessary switching in downstream logic, such as the combinational logic 210. In yet some further examples, if the upstream combinational logic (e.g., an OR gate with inputs from upstream FF circuits) settles to logic 0 during simulation of the scan shift phase, an OR-gated scan flip-flop circuit may be selected to implement the first FF circuit 202, thereby gating the data output terminal to logic 0.

In a non-limiting example, the combinational logic 210 is implemented as an AND gate, input signals received from gated data output terminals of the FF circuits 202-206 can deterministically settle to a known logic value during the scan shift phase, such as a logic 0 or logic 1. Based on this known input combination and the behavior of the AND gate, the output of the combinational logic 210 also deterministically settles to a particular logic value, such as logic 0. In this case, an OR-gated scan flip-flop circuit may be selected to implement the fourth FF circuit 208 so that a data output terminal (identified as “Q” in FIG. 2) of the fourth FF circuit 208 is gated to a logic 1, thereby reducing switching activity of downstream combinational logic. In yet another non-limiting example, the combinational logic 210 is implemented as a NAND gate. If the inputs to the NAND gate deterministically settle to logic 0 during the scan shift phase, the output of the NAND gate settles to logic 1. As a result, an AND-gated scan flip-flop circuit can be used as the fourth FF circuit 208 in the scan chain circuit 200 so that the data output terminal is gated to logic 0 of the fourth FF circuit 208, thereby reducing switching activity of downstream combinational logic.

As illustrated in FIG. 2, the FF circuits 202-208 have respective data input terminals (identified as “D” in FIG. 2) to receive input data signals or functional data input signal (identified as “DIN1,” “DIN2,” and “DIN3” in FIG. 2) from one or more upstream combinational logic circuits. In a functional mode of operation, each data input terminal receives a functional data input signal generated by upstream functional logic within the IC. A functional mode refers to the normal operation of an IC device or chip when the scan chain circuit 200 is not being used for test purposes. These functional data input signals can originate from various logic blocks or previously clocked outputs in the IC device (e.g., the chip 120 of FIG. 1) and can be used during normal circuit operation to propagate data through logic, such as sequential logic. For example, in the functional mode of operation, the FF circuits 202-206 each receive a respective one of a first, second and third input data signal (e.g., DIN1-DIN3), which can be processed and latched at a rising edge of a clock signal when a scan enable signal (identified as “SCAN” in FIG. 2) is de-asserted (e.g., at a logical low, such as 0). Output signals from the FF circuits 202-206 are then used to drive inputs of downstream combinational logic (e.g., the combinational logic 210) during the functional mode of operation. The output of the combinational logic 210 is provided as a functional data input to the data input terminal (identified as “D” in FIG. 2) of the fourth FF circuit 208. This output signal from the combinational logic 210 can be referred to as a fourth functional data input signal (identified as “DIN4” in FIG. 2), which corresponds to a logically computed value based on outputs of the FF circuits 202-206. Although the fourth functional data input signal can be present during the scan mode, the fourth functional data input signal is used for data propagation during the functional mode of operation, when the scan enable signal is de-asserted.

In some examples, the FF circuits 202-208 include scan data (SD) input terminal (identified as “SD” in FIG. 2) to receive scan data from the scan data output terminal (identified as “SQ” in FIG. 2), a preceding flip-flop in the scan chain or from an external scan input source, such as a test controller or ATE, such as the ATE 150 of FIG. 1. In some examples, the scan data can be referred to as a test vector. For example, the SD input terminal of the first FF circuit 202 receives a scan data signal (identified as “SCAN_DATA” in FIG. 2), representing a test pattern or test vector, which can be generated by the test controller or the ATE. The SD input terminal of the second FF circuit 204 is coupled to the scan data output terminal of the first FF circuit 202 to receive a first scan output signal (identified as “SQ_OUT1” in FIG. 2). The SD input terminal of the third FF circuit 206 is coupled to the scan data output terminal of the second FF circuit 204 to receive a second scan output signal (identified as “SQ_OUT2” in FIG. 2). The scan output signal represents the scan data (or a portion of the scan data, such as a bit) shifted out from a scan data output terminal of an FF circuit, corresponding to a test pattern bit (or a bit of the test vector) previously captured by that FF circuit and is passed to the SD input terminal of a next FF circuit or an external test interface.

In yet some examples, the FF circuits 202-208 include scan enable (SE) input terminals (identified as “SE” in FIG. 2) to receive a scan enable signal (identified as “SCAN” in FIG. 2). This signal controls the shift or capture phases during a scan mode of operation of the IC device or chip. Scan mode is a test operation where one or more of the FF circuits 202-208 form a shift register to load test patterns (or test vectors) or unload test results. During the shift phase, scan data is shifted serially through a scan chain (e.g., from the scan data output terminal of the first FF circuit 202 to the SD input terminal of the second FF circuit 204 and from the scan data output terminal of the second FF circuit 204 to the SD input terminal of the third FF circuit 206). During the capture phase, functional data (e.g., the fourth functional data input signal) from the combinational logic 210 is captured at the data input terminal of FF circuit 208.

The FF circuits 202-208 include clock input terminals (identified as “CLK” in FIG. 2) to receive a clock signal (identified as “CLK_SIG” in FIG. 2). The clock signal is a periodic signal generated by an on-chip clock generator, phase-locked loop (PLL), or external test equipment, such as the ATE (e.g., the ATE 150 of FIG. 1). In the functional mode of operation, the clock signal synchronizes data capture from a data input terminal to a data output terminal of the FF circuits 202-206. In the scan mode, for example, during the shift phase, the clock signal triggers the shifting of scan data through the scan chain (e.g., from SD input terminals to scan data output terminals). During the capture phase of the scan mode, the clock signal enables the capture of an output of the combinational logic 210 at the data input terminal of the fourth FF circuit 208.

For example, the FF circuits 202-208 include data output terminals (identified as “Q” in FIG. 2). The data output terminals can be used to provide a respective gated data output signal. These signals are active during functional or capture phases, when the scan enable signal is de-asserted (e.g., at a logical low, such as 0) and are suppressed during the scan shift phase by the output gating logic (e.g., the output gating logic 134 of FIG. 1). The scan data output terminals remain active (e.g., ungated) to support scan chain operations, as described herein. The data output terminal of the first FF circuit 202 is coupled to a first input terminal of the combinational logic 210 to provide a first gated data output signal (identified as “Q_OUT1” in FIG. 2). The data output terminal of the second FF circuit 204 is coupled to a second input of the combinational logic 210 to provide a second gated data output signal (identified as “Q_OUT2” in FIG. 2) and the data output terminal of the third FF circuit 206 is coupled to a third input of the combinational logic 210 to provide a third gated data output signal (identified as “Q_OUT3” in FIG. 2). The output of the combinational logic 210 is coupled to the data input terminal of the fourth FF circuit 208. The fourth FF circuit 208 includes an SD input terminal (identified as “SD” in FIG. 2), an SE input terminal (identified as “SE” in FIG. 2) to receive the scan enable signal, a clock input terminal (identified as “CLK” in FIG. 2) to receive the clock signal, a data output terminal (identified as “Q” in FIG. 2) and scan data output terminal (identified as “SQ” in FIG. 2).

In some examples, during the functional mode of operation, when the scan enable signal is de-asserted (e.g., at a logical low), the fourth FF circuit 208 captures the fourth functional data input signal corresponding to functional data from the output of the combinational logic 210 at the data input terminal on an edge of the clock signal. The captured data reflects a processed output of the combinational logic 210, which is computed based on the data output signals provided at the data output terminals of the FF circuits 202-206. This captured data (or captured value) is stored in a data storage circuit of the fourth FF circuit 208. In some examples, on a subsequent clock cycle (e.g., a next edge of the clock signal), the stored value is output at the data output terminal of the fourth FF circuit 208 as a fourth gated data output signal (e.g., Q_OUT4). The fourth gated data output signal can be used to drive downstream logic within the IC device (or chip).

In a non-limiting example, a test pattern “101” is applied as the scan data signal to the scan chain circuit 200. The combinational logic 210 receives data input signals from the data output terminals of the FF circuits 202-206. During a scan mode of operation, when the scan enable signal is asserted (e.g., is at a logical high, such as 1), the FF circuits 202-208 operate as a shift register. During the scan shift phase, scan data bits represented by the scan data signal are serially loaded through the FF circuits via the SD input and scan data output terminals. For example, in a first clock cycle, a logic 1 (e.g., a first scan data bit) is applied to the SD input terminal of the first FF circuit 202. On an edge of the first clock cycle, the first FF circuit 202 captures this bit and outputs the captured value at the scan data output terminal (e.g., as the first scan output signal SQ_OUT1). In a second clock cycle, a logic 0 (e.g., a second scan data bit) is applied to the SD input terminal of the first FF circuit 202. On an edge of the second clock cycle, the first FF circuit 202 captures the logic 0 and the previously captured logic 1 (e.g., the first scan data bit) is shifted out to the SD input terminal of the second FF circuit 204. In a third clock cycle, a logic 1 (e.g., a third scan data bit) is applied to the SD input terminal of the first FF circuit 202. On an edge of the third clock cycle, the first FF circuit 202 captures the new logic 1, the second FF circuit 204 receives logic 0 from the first FF circuit 202 and the third FF circuit 206 receives logic 1 from the second FF circuit 204. After the third clock cycle, respective data storage circuits of the FF circuits 202, 204 and 206 hold (store) logic values 1, 0 and 1, respectively, corresponding to an applied test pattern.

In some examples, during the scan shift phase, wherein the scan enable signal is at a logical high, the data output terminals of the FF circuits 202-206 are gated by respective output gating logic (e.g., the output gating logic 134) to fixed logic values (e.g., logic 0 or logic 1) to suppress switching in the combinational logic 210. When the scan enable signal is de-asserted (e.g., the scan enable signal is at a logical low, 0), a capture phase can be initiated. The output gating logic of one or more of the FF circuits 202-206 is configured to cause a respective data output terminal to drive an output signal corresponding to a stored logic value in the data storage circuits therein. For example, the first, second and third gated data output signal (e.g., Q_OUT1=1, Q_OUT2=0 and Q_OUT3=1) drive the respective input terminals of the combinational logic 210. The combinational logic 210 evaluates these inputs and generates a logic output based on a logic function that combinational logic 210 is to implement. In some examples, on an edge of a fourth clock cycle of the clock signal, the fourth FF circuit 208 captures the output of the combinational logic 210 at the data input terminal. This captured value is stored internally in the data storage circuit therein (e.g., the data storage circuit 128 of FIG. 1) and is output at the data output terminal of FF circuit 208 on a subsequent clock cycle (e.g., a fifth clock cycle), allowing for observation of a functional response of the combinational logic 210 to the applied test pattern.

Accordingly, during the scan shift phase, the data output terminals of the FF circuits 202-206 are gated to fixed values to prevent toggling at the input terminals of the combinational logic 210. During the capture phase, when the scan enable signal is de-asserted, the data output terminals are ungated and actively drive the combinational logic 210 with stored test pattern values. The combinational logic 210 processes these inputs and produces a logic output corresponding to the fourth functional data input signal. The fourth FF circuit 208 latches the logic output of the combinational logic 210 at the data input terminal. The stored (or latched) value is stored internally and can be provided at the data output terminal of the FF circuit 208, thereby enabling scan-based testing while reducing power consumption of the combinational logic 210 during the shift phase. In some examples, if the scan enable signal is asserted at a logical high in a subsequent shift phase, a stored value is output at the scan data output terminal of the fourth FF circuit 208 as a scanned out data signal (identified as “SCAN_OUT” in FIG. 2). This allows the captured value to be serially shifted out through the scan chain circuit 200 for observation by an external test controller or ATE (e.g., the ATE 150 of FIG. 1). The scanned out data signal represents a response of combinational logic 210 to the applied test pattern and can be used to verify the correctness of a logic behavior of the combinational logic 210 during scan-based testing.

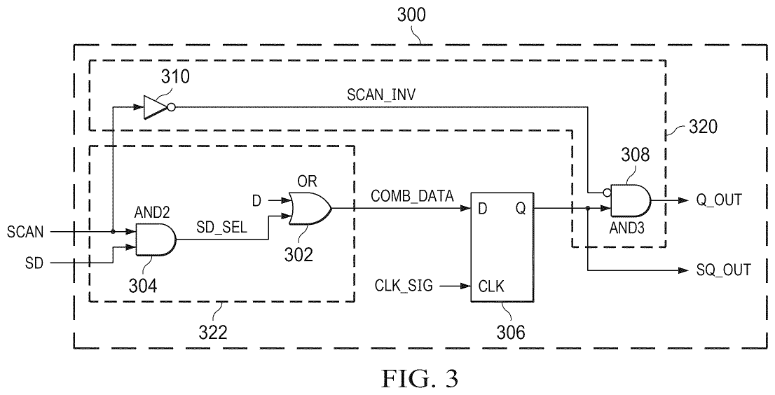

FIG. 3 is an example of a block diagram of an output-gated scan FF circuit corresponding to an OR-gated scan FF circuit 300. The OR-gated scan FF circuit 300 can be used as one of the FF circuits 202-208 of the scan chain circuit 200 of FIG. 2. For example, the OR-gated scan FF circuit 300 can be selected for implementation of a respective FF circuit (e.g., the first FF circuit 202) when a corresponding data input signal is expected to deterministically settle to a logic 0 value during a scan shift phase of scan mode (e.g., when SCAN=1). In such a case, output gating logic of the OR-gated scan FF circuit 300 suppresses toggling at the data output terminal by forcing the gated data output signal to a logic 0 value. The OR-gated scan FF circuit 300 includes data selection logic 322, output gating logic 320 and a storage FF circuit 306 corresponding to a data storage circuit (e.g., the data storage circuit 128 of FIG. 1). The data selection logic 322 includes an OR gate 302 and a first AND gate 304. The output gating logic 320 includes a second AND gate 308 and an inverter 310. The first AND gate 304 has a first input to receive a scan enable signal (identified as “SCAN” in FIG. 3), which corresponds to the scan enable signal received at the SE input terminal of one of the FF circuits 202-208. The first input of the first AND gate 304 can be coupled to the SE input terminal. A second input of the first AND gate 304 receives a scan data input signal (identified as “SD” in FIG. 3), which can correspond to the scan data signal SCAN_DATA, the first scan output signal SQ_OUT1 or the second scan output signal SQ_OUT2 of FIG. 2. The second input of the first AND gate 304 can be coupled to the SD input terminal.

In operation, the output of the first AND gate 304 provides a scan data selection signal (identified as “SD_SEL” in FIG. 3) to a first input of the OR gate 302. A second input of the OR gate 302 receives a functional data input signal (identified as “D” in FIG. 3) corresponding to a data input signal such as one of the first, second, third and fourth functional data input signal DIN1, DIN2, DIN3 and DIN4 of FIG. 2. The OR gate 302 outputs a combined data signal (identified as “COMB_DATA” in FIG. 3), which can be based on a logical OR of the scan data selection signal and the data input signal. For example, when the data input signal is a logic 0, the combined data signal equals the scan data selection signal (e.g., COMB_DATA=SD|0=SD), thereby allowing for accurate scan data capture during the scan shift phase. The combined data signal can be provided to a storage data input terminal (identified as “D” in FIG. 2) of the storage FF circuit 306. A storage clock input terminal of the storage FF circuit 306 receives a clock signal (identified as “CLK_SIG” in FIG. 3). The storage clock input terminal can correspond to the clock input terminal of the OR-gated scan FF circuit 300.

In some examples, during operation, a storage data output terminal of the storage FF circuit 306 (identified as “Q” in FIG. 3) provides a scan output signal (identified as “SQ_OUT” in FIG. 3) that corresponds to a stored logic value in the storage FF circuit 306. The storage data output terminal of the storage FF circuit 306 can be referred to as, or electrically coupled to, the scan data output terminal of the OR-gated scan FF circuit 300. The stored logic value represents a logic state captured at the storage data input terminal of the storage FF circuit 306. The storage data output terminal of the storage FF circuit 306 can be coupled to a first input of the second AND gate 308. A second input of the second AND gate 308 is coupled to an output of the inverter 310 to receive an inverted scan enable signal (identified as “SCAN_INV”). The output of the second AND gate 308 provides a gated data output signal (identified as “Q_OUT” in FIG. 3), which is suppressed during the scan shift phase and active during the capture phase of the scan chain circuit 200 of FIG. 2. The output of the second AND gate 308 can be referred to as, or electrically coupled to, the data output terminal (e.g., the data output terminal) of the OR-gated scan FF circuit 300.

By way of example, the first FF circuit 202 of FIG. 2 is implemented using the OR-gated scan FF circuit 300 and the corresponding data input signal DIN1 is expected to deterministically settle to logic 0 during the scan shift phase (e.g., when the scan enable signal SCAN is asserted at a logical high level). During this scan shift phase, the scan enable signal is received at the SE input terminal and asserted (SCAN=1) and a scan data input signal of logic 1 is applied to the SD input terminal. The first AND gate 304 receives SCAN=1 and SD=1 and outputs a logic 1 value as the scan data selection signal (SD_SEL). The OR gate 302 receives SD_SEL=1 and D=0 and outputs a combined data signal (COMB_DATA=1), which is provided to the storage data input terminal of the storage FF circuit 306. On an edge of the clock signal (CLK_SIG), the storage FF circuit 306 captures and stores the logic 1 value, updating its internal state. The stored logic value is output at the storage data output terminal of the storage FF circuit 306 and applied to a first input of the second AND gate 308. During the scan shift phase, the output gating logic 320 suppresses toggling at the data output terminal by forcing the gated data output signal (Q_OUT) to a fixed logic value, based on the expected settled value of the data input signal. In this case, since the data input signal D is expected to settle to logic 0, the gated data output signal is forced to logic 0. To implement this behavior, the second AND gate 308 may be replaced or functionally equivalent to an OR gate with a first input receiving the stored logic value and a second input receiving the scan enable signal SCAN. When SCAN is asserted (e.g., SCAN=1), the OR gate outputs a logic 1 value at Q_OUT, regardless of the stored value, thereby gating the data output terminal to a fixed logic 1 during the scan shift phase. This output gating prevents transitions at the data output terminal, suppressing switching activity in downstream combinational logic, such as the combinational logic 210 of FIG. 2. The suppression reduces dynamic power dissipation, mitigates IR drop and improves power integrity during scan-based test operations. In a subsequent capture phase, when the scan enable signal is de-asserted (e.g., SCAN=0), the inverter 310 outputs logic 1 (SCAN_INV=1), enabling the second AND gate 308 to propagate the stored logic value from the storage FF circuit 306 to the data output terminal as the gated data output signal (Q_OUT1). During this capture phase, the SD input terminal is inactive and the functional data input path is restored. Accordingly, the OR-gated scan FF circuit 300 maintains scan output functionality via the scan data output terminal (e.g., SQ_OUT), while selectively gating the data output terminal during the scan shift phase to reduce power consumption and maintain signal stability during scan-based testing.

In the functional mode of operation, when the scan enable signal is de-asserted (SCAN=0), the scan data input path is disabled and the OR gate 302 operates based solely on the functional data input signal (D). In this state, the output of the first AND gate 304 is logic 0 (SD_SEL=0) and the combined data signal (COMB_DATA) provided by the OR gate 302 equals the functional data input signal (e.g., COMB_DATA=D|0=D). On an edge of the clock signal, the storage FF circuit 306 captures and stores the functional data input signal and the stored logic value is propagated to the data output terminal (Q_OUT) through the second AND gate 308, which is enabled by the inverted scan enable signal (SCAN_INV=1). As a result, the OR-gated scan FF circuit 300 behaves as a conventional flip-flop in functional mode, allowing normal data capture and propagation through the scan chain circuit 200.

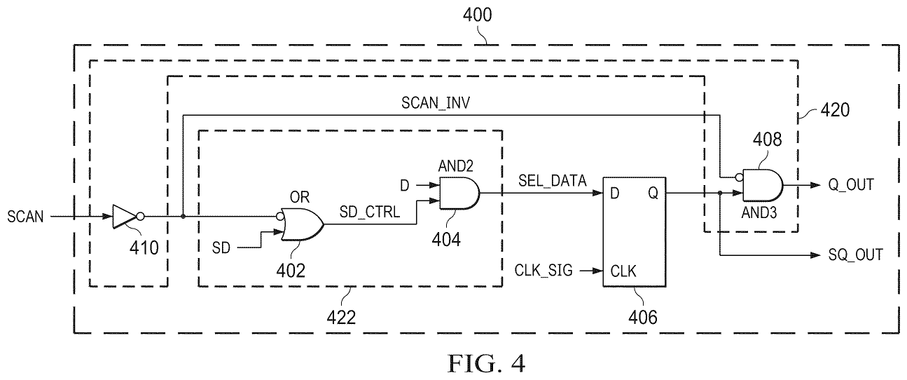

FIG. 4 illustrates an example block diagram of an output-gated scan FF circuit corresponding to an AND-gated scan FF circuit 400. The AND-gated scan FF circuit 400 can be used to implement one or more of the FF circuits 202-208 of the scan chain circuit 200 of FIG. 2. For example, the AND-gated scan FF circuit 400 can be selected for implementation of a respective FF circuit (e.g., the second FF circuit 204) when a corresponding data input signal is expected to deterministically settle to a logic 1 value during a scan shift phase of scan mode (e.g., when SCAN=1). In such a case, output gating logic of the AND-gated scan FF circuit 400 suppresses toggling at the data output terminal by forcing the gated data output signal to a logic 0 value. For example, the AND-gated scan FF circuit 400 can be used when a corresponding data input terminal (identified as “D” in FIG. 2) of a respective FF circuit (e.g., the second FF circuit 204) is expected to deterministically settle to a logic 1 value during the scan shift phase of scan mode (e.g., when SCAN=1). The AND-gated scan FF circuit 400 includes data selection logic 422, gating logic 420 and a storage FF circuit 406 corresponding to a data storage circuit (e.g., the data storage circuit 128 of FIG. 1). The data selection logic 422 includes a first AND gate 404 and an OR gate 402. The gating logic 420 includes a second AND gate 408 and an inverter 410.

In some examples, a first input of the AND gate 404 receives a functional data input signal (identified as “D” in FIG. 4), which can correspond to one of the functional data input signals DIN1-DIN4 of FIG. 2. A second input of the AND gate 404 receives a scan data control signal (identified as “SD_CTRL” in FIG. 4) generated by the OR gate 402. The OR gate 402 has a first input to receive a scan data input signal (identified as “SD” in FIG. 4), which can correspond to the scan data signal SCAN_DATA, the first scan output signal SQ_OUT1 or the second scan output signal SQ_OUT2 of FIG. 2. The first input of the OR gate 402 can be coupled to the SD input terminal. A second input of the OR gate 402 receives an inverted scan enable signal (identified as “SCAN_INV”), which is generated by the inverter 410. An input of the inverter 410 receives the scan enable signal (identified as “SCAN” in FIG. 4). The input of the inverter 410 can be coupled to the SE input terminal of one of the FF circuits 202-208.

In some examples, the OR gate 402 outputs the scan data control signal, which evaluates to logic 1 if either the scan data input signal is at logic 1 or the scan enable signal is de-asserted (e.g., at a logical low, 0). An output of the AND gate 404 provide a selected data signal (identified as “SEL_DATA” in FIG. 4) representing a logical AND of the functional data input signal and scan data control signal (e.g., SEL_DATA=D & SD_CTRL). The selected data signal is applied to a storage data input terminal of the storage FF circuit 406, while a clock signal (identified as “CLK_SIG” in FIG. 4) is applied to a storage clock input terminal (identified as “CLK” in FIG. 4) of the storage FF circuit 406. The storage clock input terminal can correspond to the clock input terminal of the AND-gated scan FF circuit 400. The storage FF circuit 406 captures and stores the selected data signal (e.g., logic value) on an edge of the clock signal. A storage data output terminal (identified as “Q” in FIG. 4) of the storage FF circuit 406 provides a stored logic value, which corresponds to scan output signal (identified as “SQ_OUT” in FIG. 4) and is also applied to a first input of the second AND gate 408. In some examples, a second input of the second AND gate 408 is coupled to receive the inverted scan enable signal from the inverter 410. The output of the second AND gate 408 provides a gated data output signal (identified as “Q_OUT” in FIG. 4), which is suppressed during the scan shift phase (e.g., when SCAN=1, SCAN_INV=0) and becomes active during the capture or functional phase (e.g., when SCAN=0, SCAN_INV=1). The gated data output signal can be referred to as, or electrically coupled to, the data output terminal of the AND-gated scan FF circuit 400.

By way of example, the second FF circuit 204 of FIG. 2 can be implemented as the AND-gated scan FF circuit 400. In this example, the functional data input signal, corresponding to DIN2 of FIG. 2, is expected to deterministically settle to logic 1 during the scan shift phase (e.g., when the scan enable signal SCAN is asserted at a logical high). This aligns with the selection criteria for an AND-gated scan flip-flop circuit, which gates the data output terminal to logic 0 during the scan shift phase to suppress switching activity in downstream combinational logic, such as the combinational logic 210. During this phase, the inverter 410 receives SCAN=1 and outputs an inverted scan enable signal SCAN_INV=0 to the OR gate 402 and the second AND gate 408. The OR gate 402 also receives a scan data input signal SD=1 at its first input terminal and outputs the scan data control signal SD_CTRL=1. The first AND gate 404 receives the functional data input signal D=1 and SD_CTRL=1 and outputs a selected data signal SEL_DATA=1. The selected data signal SEL_DATA is applied to the storage data input terminal of the storage FF circuit 406. On an edge of the clock signal CLK_SIG, the storage FF circuit 406 captures and stores the logic 1 value, updating an internal state. The stored logic value appears at the storage data output terminal of the storage FF circuit 406 (identified as “Q” in FIG. 4) and is provided as the scan output signal and applied to a first input of the second AND gate 408. Because the inverted scan enable signal SCAN_INV=0 during the scan shift phase, the second AND gate 408 suppresses the stored logic value at its output, resulting in a gated data output signal Q_OUT=0. This output gating suppresses switching activity at the data output terminal of the second FF circuit 204, thereby reducing unnecessary toggling in downstream combinational logic, such as the combinational logic 210 of FIG. 2. In a subsequent capture phase, when the scan enable signal SCAN is de-asserted (e.g., at a logical low), the inverter 410 outputs SCAN_INV=1. The second AND gate 408 then receives logic 1 at both inputs (the stored logic value from the storage FF circuit 406 and SCAN_INV=1) and outputs the gated data output signal Q_OUT=1. Accordingly, during the capture or functional phases, the AND-gated scan FF circuit 400 propagates the stored logic value to the data output terminal while maintaining scan output functionality via the scan data output terminal SQ_OUT. This output gating behavior enables suppression of toggling at Q_OUT during the scan shift phase, thereby reducing dynamic power dissipation, improving power integrity and maintaining accurate data propagation in the scan chain circuit 200.

In the functional mode of operation, when the scan enable signal is de-asserted (SCAN=0), the inverter 410 outputs an inverted scan enable signal SCAN_INV=1. The OR gate 402 receives SCAN_INV=1 and outputs a scan data control signal SD_CTRL=1. The first AND gate 404 performs a logical AND between the functional data input signal D and SD_CTRL=1, resulting in a selected data signal SEL_DATA equal to the functional data input signal (e.g., SEL_DATA=D & 1=D). The selected data signal is applied to the storage data input terminal of the storage FF circuit 406. On an edge of the clock signal CLK_SIG, the storage FF circuit 406 captures and stores the functional data input signal, which is output at the storage data output terminal and applied to a first input of the second AND gate 408. With SCAN_INV=1 at the second input, the second AND gate 408 propagates the stored logic value to the data output terminal as the gated data output signal Q_OUT. Accordingly, during the functional mode, the AND-gated scan FF circuit 400 behaves as a conventional flip-flop, capturing and forwarding functional data values to downstream logic while maintaining scan chain connectivity via the scan data output terminal (SQ_OUT).

In some examples, the OR-gated scan FF circuit 300 and/or the AND-gated scan FF circuit 400 can be implemented using 38 transistors, compared to about 40 transistors used to implement a conventional non-gated scan FF circuit with external gating circuitry, resulting in a lower area overhead of about 17%. The reduced area overhead of about 17%, achieved by using fewer transistors compared to conventional non-gated scan FF circuits with external gating circuits, enables more compact scan chain circuit designs, such as for low-area IC devices (e.g., used in safety-critical automotive applications), thereby by lowering manufacturing costs and improving design efficiency without compromising scan test performance.

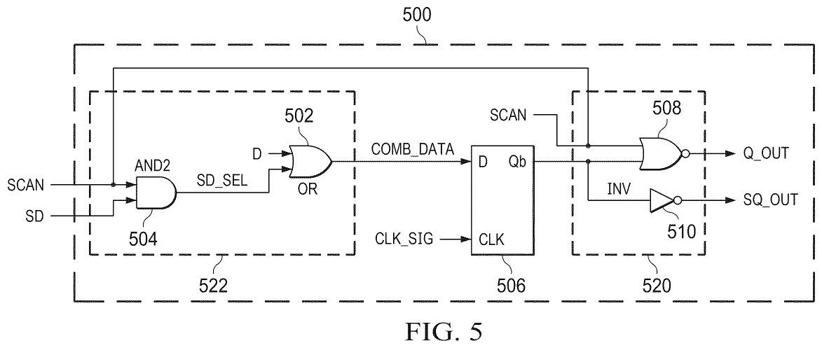

FIG. 5 is an example of a block diagram of an output-gated scan FF circuit 500, which can be referred to as an OR-gated scan FF circuit 500. The OR-gated scan FF circuit 500 can be used to implement one or more of the FF circuits 202-208 of the scan chain circuit 200 of FIG. 2. For example, the OR-gated scan FF circuit 500 can be selected for implementation of a respective FF circuit (e.g., the first FF circuit 202) when a corresponding data input signal is expected to deterministically settle to a logic 0 value during a scan shift phase of scan mode (e.g., when SCAN=1). The OR-gated scan FF circuit 500 includes self-compensated output gating logic that uses an inverted output of a storage FF circuit and the scan enable signal to suppress toggling at the data output terminal by forcing the gated data output signal to logic 0. The OR-gated scan FF circuit 500 includes data selection logic 522, output gating logic 520 and a storage FF circuit 506. The data selection logic 522 includes an OR gate 502 and an AND gate 504. The output gating logic 520 includes a NOR gate 508 and an inverter 510. The AND gate 504 has a first input to receive a scan enable signal (identified as “SCAN” in FIG. 5), which can correspond to the scan enable signal received at the SE input terminal of one of the FF circuits 202-208 of FIG. 2. A second input of the AND gate 504 receives a scan data input signal (identified as “SD” in FIG. 5), which can correspond to the scan data signal SCAN_DATA, the first scan output signal SQ_OUT1 or the second scan output signal SQ_OUT2 of FIG. 2.

In operation, the output of the AND gate 504 provides a scan data selection signal (identified as “SD_SEL” in FIG. 5) to a first input of the OR gate 502. A second input of the OR gate 502 receives a functional data input signal (identified as “D” in FIG. 5), corresponding to a data input signal such as one of the functional data input signals DIN1-DIN4 of FIG. 2. The OR gate 502 performs a logical OR operation on the scan data selection signal and the functional data input signal to generate a combined data signal (identified as “COMB_DATA” in FIG. 5). For example, when the functional data input signal is expected to deterministically settle to logic 0 during the scan shift phase, the combined data signal equals the scan data selection signal (e.g., COMB_DATA=SD|0=SD), thereby allowing scan data shifting. The combined data signal is applied to a storage data input terminal (identified as “D” in FIG. 5) of the storage FF circuit 506, which also receives a clock signal (identified as “CLK_SIG” in FIG. 5) at a storage clock input terminal (identified as “CLK” in FIG. 5). The storage clock input terminal can correspond to the clock input terminal of the output-gated scan FF circuit 500.

During operation, the storage FF circuit 506 captures and stores the combined data signal on an edge of the clock signal as a logical state. The storage FF circuit 506 provides an inverted output signal (identified as “INV” in FIG. 5), which is an inverted representation of the stored logical state at an inverted data output terminal (identified as “Qb” in FIG. 5). Thus, the inverted output signal at the inverted data output terminal corresponds to a logical complement of a logic value captured and stored within the storage FF circuit 506 based on the combined data signal. The inverted data output terminal of the storage FF circuit 506 is coupled to an input of the inverter 510 and to a first input of the NOR gate 508 to receive the inverted output signal. A second input of the NOR gate 508 receives the scan enable signal and thus can be coupled to the SE input terminal of the OR-gated scan FF circuit 500. The inverter 510 inverts the inverted output signal at the inverted data output terminal to provide a scan output signal (identified as “SQ_OUT” in FIG. 5), which represents the stored logic value and supports scan shift operations. The output of the inverter 510 can be referred to as, or electrically coupled to, a scan data output terminal of the OR-gated scan FF circuit 500.

For example, the NOR gate 508 evaluates the inverted output signal and the scan enable signal to generate a gated data output signal (identified as “Q_OUT” in FIG. 5) at an output. The output of the NOR gate 508 can be referred to as, or electrically coupled to, a data output terminal of the OR-gated scan FF circuit 500. In some examples, during the scan shift phase, when the scan enable signal is asserted at a logical high, the NOR gate 508 suppresses a data output by forcing the gated data output signal to a logic 0, thereby reducing switching activity in downstream combinational logic (e.g., the combinational logic 210 of FIG. 2). During a capture or functional phase, when the scan enable signal is de-asserted (e.g., is at a logical low, 0), the NOR gate 508 propagates a complement of the stored logic value from the storage FF circuit 506 to the data output terminal of the OR-gated scan FF circuit 500 as the gated data output signal. Accordingly, the OR-gated scan FF circuit 500 provides self-compensated output gating by utilizing the inverted output signal at the inverted data output terminal of the storage FF 506 and the scan enable signal to determine an appropriate output behavior. The scan output signal can remain active to support scan shift operations, while the gated data output signal is selectively enabled based on the scan enable signal to suppress dynamic power consumption during scan shift phases and maintain accurate logic propagation during capture or functional phases.

By way of example, the first FF circuit 202 of FIG. 2 is implemented using the OR-gated scan FF circuit 500 and the corresponding data input signal DIN1 is expected to deterministically settle to logic 0 during the scan shift phase (e.g., when the scan enable signal SCAN is asserted at a logical high level). During the scan shift phase, the scan enable signal is received at the SE input terminal and asserted (SCAN=1) and a scan data input signal having a logic 1 value is applied to the SD input terminal. The AND gate 504 receives SCAN=1 and SD=1 and outputs a logic 1 value as the scan data selection signal (SD_SEL). The OR gate 502 receives the scan data selection signal (SD_SEL=1) and the functional data input signal (D=0) and generates a combined data signal (COMB_DATA=1), which is applied to the data input terminal of the storage FF circuit 506. On an edge of the clock signal (CLK_SIG), the storage FF circuit 506 captures and stores the combined data signal as a logical state. The storage FF circuit 506 then provides an inverted output signal at an inverted data output terminal, where the inverted output signal corresponds to the logical complement of the stored logic value. The inverted output signal is applied to an input of the inverter 510 and a first input of the NOR gate 508. The inverter 510 generates a scan output signal (SQ_OUT) representing the stored logic value and provides the scan output signal at a scan data output terminal of the OR-gated scan FF circuit 500. The NOR gate 508 receives the inverted output signal (INV=0) and the scan enable signal (SCAN=1) at its respective inputs and outputs a logic 0 value as the gated data output signal (Q_OUT), thereby forcing the data output terminal to logic 0 during the scan shift phase. This output gating suppresses toggling activity at the data output terminal, reducing switching transitions at input terminals of downstream combinational logic, such as the combinational logic 210 of FIG. 2. In a subsequent capture phase, when the scan enable signal is de-asserted (SCAN=0), the NOR gate 508 receives INV=0 and SCAN=0 and outputs a logic 1 value as the gated data output signal (Q_OUT). This value is actively driven at the data output terminal and represents the logical complement of the inverted output signal. Accordingly, the OR-gated scan FF circuit 500 maintains active scan output functionality via the scan data output terminal while providing self-compensated output gating at the data output terminal based on the inverted output signal and the scan enable signal. This enables suppression of switching transitions during scan shifting, thereby reducing power consumption and improving signal integrity during scan-based test operations.

In the functional mode of operation, when the scan enable signal is de-asserted (SCAN=0), the scan data input path is disabled and the AND gate 504 receives SCAN=0 and outputs a logic 0 as the scan data selection signal (SD_SEL=0), regardless of the SD input. The OR gate 502 receives SD_SEL=0 and the functional data input signal (D) and generates a combined data signal (COMB_DATA=D), which is applied to the data input terminal of the storage FF circuit 506. On an edge of the clock signal (CLK_SIG), the storage FF circuit 506 captures and stores the functional data input signal as a logic state. The stored logic value is inverted and provided as an inverted output signal at the inverted data output terminal, which is then used by both the inverter 510 and the NOR gate 508. Since the scan enable signal remains at a logical low level (SCAN=0), the NOR gate 508 propagates the logical complement of the inverted output signal as the gated data output signal (Q_OUT). As a result, the OR-gated scan FF circuit 500 operates as a conventional flip-flop during functional mode, capturing functional data values and actively driving the data output terminal while continuing to support scan shift functionality via the scan data output terminal (SQ_OUT).

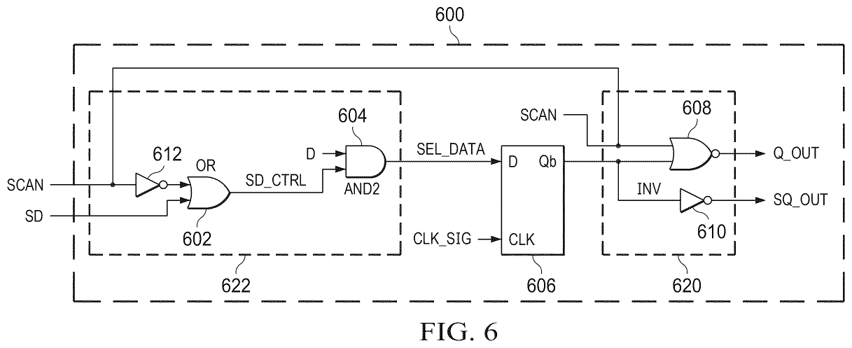

FIG. 6 illustrates an example block diagram of an output-gated scan FF circuit, which can be referred to as an AND-gated scan FF circuit 600. The AND-gated scan FF circuit 600 can be used to implement one or more of the FF circuits 202-208 of the scan chain circuit 200 of FIG. 2. For example, the AND-gated scan FF circuit 600 can be selected for implementation of a respective FF circuit (e.g., the second FF circuit 204) when a corresponding data input signal is expected to deterministically settle to a logic 1 value during a scan shift phase of scan mode (e.g., when SCAN=1). The AND-gated scan FF circuit 600 includes data selection logic 622, output gating logic 620 and a storage FF circuit 606 corresponding to a data storage circuit (e.g., the data storage circuit 128 of FIG. 1). The data selection logic 622 includes an AND gate 604, an OR gate 602 and a first inverter 612. The output gating logic 620 includes a NOR gate 608 and a second inverter 610.

For example, a first input of the AND gate 604 receives a functional data input signal (identified as “D” in FIG. 6), which can correspond to one of the functional data input signals DIN1-DIN4 of FIG. 2. A second input of the AND gate 604 receives a scan data control signal (identified as “SD_CTRL” in FIG. 6), which is generated at an output of the OR gate 602. A first input of the OR gate 602 receives an inverted scan enable signal (identified as “SCAN_INV” in FIG. 6), which is generated at an output of the first inverter 612 to which the first input of the OR gate 602 is coupled. The first inverter 612 receives a scan enable signal (identified as “SCAN” in FIG. 6) at an input terminal, which can correspond to the SE input terminal of one of the FF circuits 202-208 of FIG. 2. A second input of the OR gate 602 receives a scan data input signal (identified as “SD” in FIG. 6), which can correspond to the scan data signal SCAN_DATA, the first scan output signal SQ_OUT1 or the second scan output signal SQ_OUT2 of FIG. 2. The OR gate 602 outputs the scan data control signal, which evaluates to logic 1 if either the scan data input signal is asserted or the scan enable signal is de-asserted. Accordingly, the scan data control signal enables selection of functional data during functional or capture phases and selection of scan data during scan shift phases.

In some examples, an output of the AND gate 604 generates a selected data signal (identified as “SEL_DATA” in FIG. 6), representing a logical AND of the functional data input signal and the scan data control signal (e.g., SEL_DATA=D & SD_CTRL). The selected data signal is applied to a storage data input terminal (identified as “D” in FIG. 6) of the storage FF circuit 606. A clock signal (identified as “CLK_SIG” in FIG. 6) is applied to a clock input terminal (identified as “CLK” in FIG. 6) of the storage FF circuit 606. The storage clock input terminal can correspond to the clock input terminal of the AND-gated scan FF circuit 600. On an edge of the clock signal, the storage FF circuit 606 captures and stores the selected data signal as a logic value (or logical state) representing an internal state.

For example, during operation, the storage FF circuit 606 provides an inverted output signal (identified as “INV” in FIG. 6), which is an inverted representation of the stored logical state at an inverted data output terminal (identified as “Qb” in FIG. 6). Thus, the inverted output signal at the inverted data output terminal corresponds to a logical complement of a logic value captured and stored within the storage FF circuit 606 based on the selected data signal. The inverted data output terminal of the storage FF circuit 606 is coupled to an input of the second inverter 610 and to a first input of the NOR gate 608 to receive the inverted output signal. A second input of the NOR gate 608 receives the scan enable signal and thus can be coupled to the SE input terminal of the AND-gated scan FF circuit 600. The second inverter 610 inverts the inverted output signal at the inverted data output terminal to provide a scan output signal (identified as “SQ_OUT” in FIG. 6), which represents the stored logic value and supports scan shift operations. The output of the second inverter 610 can be referred to as, or electrically coupled to, a scan data output terminal of the AND-gated scan FF circuit 600.

For example, the NOR gate 608 evaluates the inverted output signal and the scan enable signal to generate a gated data output signal (identified as “Q_OUT” in FIG. 6) at an output. The output of the NOR gate 608 can be referred to as, or electrically coupled to, a data output terminal of the AND-gated scan FF circuit 600. In some examples, during the scan shift phase, when the scan enable signal is asserted at a logical high, the NOR gate 608 suppresses a data output by forcing the gated data output signal to a logic 0, thereby reducing switching activity in downstream combinational logic (e.g., the combinational logic 210 of FIG. 2). During a capture or functional phase, when the scan enable signal is de-asserted (e.g., is at a logical low, 0), the NOR gate 608 propagates a complement of the stored logic value from the storage FF circuit 606 to the data output terminal of the AND-gated scan FF circuit 600 as the gated data output signal. Accordingly, the AND-gated scan FF circuit 600 provides self-compensated output gating by utilizing the inverted output signal at the inverted data output terminal of the storage FF 606 and the scan enable signal to determine an appropriate output behavior. The scan output signal can remain active to support scan shift operations, while the gated data output signal is selectively enabled based on the scan enable signal to suppress dynamic power consumption during scan shift phases and maintain accurate logic propagation during capture or functional phases.

By way of example, the second FF circuit 204 of FIG. 2 is implemented using the AND-gated scan FF circuit 600 and the corresponding data input signal DIN2 is expected to deterministically settle to logic 1 during the scan shift phase (e.g., when the scan enable signal SCAN is asserted at a logical high level). During the scan shift phase, the scan enable signal is received at the SE input terminal and asserted (SCAN=1) and a scan data input signal having a logic 1 value is applied to the SD input terminal. The first inverter 612 receives the asserted scan enable signal and outputs an inverted scan enable signal SCAN_INV=0. The OR gate 602 receives SCAN_INV=0 and SD=1 and outputs a scan data control signal SD_CTRL=1. The AND gate 604 receives the functional data input signal D=1 and the scan data control signal SD_CTRL=1 and outputs a selected data signal SEL_DATA=1, which is applied to the data input terminal of the storage FF circuit 606. On an edge of the clock signal (CLK_SIG), the storage FF circuit 606 captures and stores the selected data signal as a logical state. The storage FF circuit 606 then provides an inverted output signal at the inverted data output terminal, where the inverted output signal corresponds to the logical complement of the stored logic value (e.g., INV=0). The inverted output signal is applied to an input of the second inverter 610 and to a first input of the NOR gate 608. The second inverter 610 inverts the inverted output signal and provides a scan output signal (SQ_OUT) representing the stored logic value at a scan data output terminal. The NOR gate 608 receives the inverted output signal (INV=0) and the scan enable signal (SCAN=1) and outputs a logic 0 value as the gated data output signal (Q_OUT), thereby gating the data output terminal to logic 0 during the scan shift phase. This output gating suppresses toggling activity at the data output terminal, reducing switching transitions at input terminals of downstream combinational logic, such as the combinational logic 210 of FIG. 2. In a subsequent capture phase, when the scan enable signal is de-asserted (SCAN=0), the first inverter 612 outputs SCAN_INV=1. The NOR gate 608 receives INV=0 and SCAN=0 and outputs a logic 1 value as the gated data output signal (Q_OUT). This value is actively driven at the data output terminal and represents the logical complement of the inverted output signal. Accordingly, the AND-gated scan FF circuit 600 maintains active scan output functionality via the scan data output terminal while providing self-compensated output gating at the data output terminal based on the inverted output signal and the scan enable signal. This enables suppression of switching transitions during scan shifting, thereby reducing power consumption and improving signal integrity during scan-based test operations.

In the functional mode of operation, when the scan enable signal is de-asserted (SCAN=0), the scan data path is disabled and the first inverter 612 outputs SCAN_INV=1. The OR gate 602 receives SCAN_INV=1 and outputs a scan data control signal SD_CTRL=1. The AND gate 604 performs a logical AND between the functional data input signal D and the scan data control signal SD_CTRL=1, resulting in a selected data signal SEL_DATA equal to the functional data input signal (e.g., SEL_DATA=D & 1=D). On an edge of the clock signal (CLK_SIG), the storage FF circuit 606 captures and stores the functional data input signal as a logic state. The stored logic value is inverted and provided as the inverted output signal at the inverted data output terminal. The second inverter 610 inverts the inverted output signal to generate the scan output signal (SQ_OUT), while the NOR gate 608 receives the inverted output signal and the de-asserted scan enable signal (SCAN=0) and propagates the complement of the inverted output signal as the gated data output signal (Q_OUT). As a result, the AND-gated scan FF circuit 600 operates as a conventional flip-flop during functional mode, capturing and forwarding functional data values to downstream logic while maintaining scan shift functionality via the scan data output terminal (SQ_OUT).

In some examples, the OR-gated scan FF circuit 500 and/or the AND-gated scan FF circuit 600 can be implemented using 32 transistors, compared to about 40 transistors used to implement a conventional non-gated scan FF circuit with external gating circuitry, resulting in a lower area overhead of about 20%. The reduced area overhead of about 20%, achieved by using fewer transistors compared to conventional non-gated scan FF circuits with external gating circuits, enables more compact scan chain circuit designs, such as for low-area IC devices (e.g., used in safety-critical automotive applications), thereby by lowering manufacturing costs and improving design efficiency without compromising scan test performance.

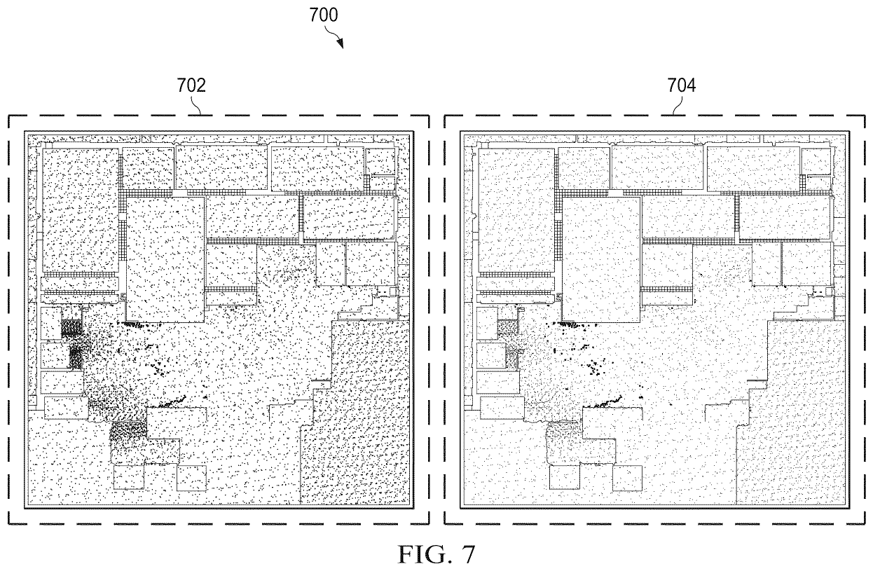

FIG. 7 illustrates an example of a comparative analysis 700 of IR drop observed during scan-based testing in an integrated circuit (IC) device, such as a system-on-chip (SoC), using first and second heat maps 702 and 704. IR drop distributions are visualized using heat maps generated during the simulation of an IC design for the IC device, such as the chip 120 of FIG. 1. The heat maps represent voltage drop distributions during a scan shift phase of scan mode at a clock frequency of about 25 MHz. The first heat map 702 corresponds to a SoC including a scan chain circuit composed of conventional flip-flops, which do not incorporate the output gating logic of the output-gated scan FF circuits described herein (e.g., the OR-gated scan FF circuits 300 and 500 of FIGS. 3 and 5, or the AND-gated scan FF circuits 400 and 600 of FIGS. 4 and 6). In contrast, the second heat map 704 corresponds to the SoC implementation of chip 120 of FIG. 1, which includes the scan chain circuit 122 (e.g., the scan chain circuit 200 of FIG. 2) that utilizes one or more of the output-gated scan FF circuits for power-efficient scan operation.

The first and second heat maps 702 and 704 illustrate IR drop (i.e., voltage drop due to current flow through resistive interconnects) across a SoC, including about 70,000 flip-flops, operating at a minimum supply voltage (V_MIN) of about 1.2 volts. In this example, the IR drop closure target for scan-based testing is defined as a maximum drop of 204 millivolts (mV), corresponding to 17% of V_MIN (0.17×1.2V). As shown in the first heat map 702, the scan chain circuit using conventional flip-flops results in more than 50% of flip-flops and associated downstream combinational logic experiencing IR drops that exceed this threshold during the scan shift phase, when the scan enable signal is asserted (e.g., SCAN=1). The excessive IR drop is caused by toggling activity at the data output terminals (e.g., Q outputs) of the flip-flops, which in turn induces unnecessary signal transitions in connected combinational logic. These transitions increase dynamic power dissipation and can lead to timing violations, rail noise and scan test failures due to reduced voltage margins. The second heat map 704 shows that the SoC incorporating the output-gated scan FF circuits maintains IR drop within 15% of V_MIN (i.e., ≤180 mV) for 99.92% of flip-flops and associated combinational logic. This improvement results from the output gating logic within the output-gated scan FF circuits, which suppresses toggling activity at the data output terminals during the scan shift phase, when the scan enable signal is asserted (SCAN=1). By gating the data output terminals (e.g., forcing them to a fixed logic value based on deterministic settling), the output-gated scan FF circuits reduce transitions at input terminals of downstream combinational logic (e.g., the combinational logic 210 of FIG. 2), thereby reducing dynamic power consumption. This results in an average power reduction of more than 42% during scan shift operations compared to conventional flip-flop-based scan chains, enabling reliable test execution without the need for additional power management structures (e.g., power switches or domain gating). In addition to the reduced IR drop, the output-gated scan FF circuits offer layout efficiency advantages. Compared to a conventional scan flip-flop design, use of the proposed scan FF circuits results in a sequential logic area reduction of about 7%, translating to an estimated area savings of about 55,385 square micrometers (μm²) in an SoC with 70,000 flip-flops. For example, this area reduction is comparable to the footprint of about 8 kilobytes (KB) of SRAM in an IC device (e.g., the chip 120 of FIG. 1) in the same process node. By maintaining IR drop within acceptable limits, the scan FF circuits eliminate the need for area-consuming power switches that would otherwise be required in conventional designs to mitigate IR drop through power gating. Furthermore, the consistent suppression of toggling activity during the scan shift phase eliminates the need for a large number of iterative simulation steps, such as value change dump (VCD) waveform analysis, which are traditionally used to identify IR drop violations during tape out. As a result, the output-gated scan FF circuits improve test reliability, power integrity, simplify timing closure, and reduce overall design verification effort.

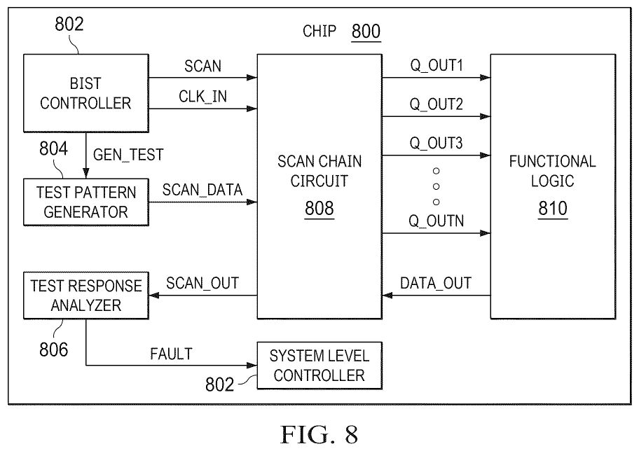

FIG. 8 illustrates an example of a chip 800, which in some instances can correspond to the chip 120 of FIG. 1. In some examples, the chip 800 is configured to perform scan testing to verify the functionality of functional logic 810, such as combinational logic, sequential logic, or memory elements, during operation in safety-critical applications, such as when the chip 800 is deployed or when the ATE 150 is unavailable. In some examples, the functional logic 810 corresponds to the functional logic 130 of FIG. 1. To enable scan testing of the functional logic 810, the chip 800 includes an on-chip built-in self-test (BIST) controller 802, a test pattern generator 804 and a test response analyzer 806, as illustrated in FIG. 8. The BIST controller 802, which can be implemented as a finite state machine or microcontroller, orchestrates scan testing by generating control signals, including a scan enable signal (identified as “SCAN” in FIG. 8) and a clock signal (identified as “CLK_IN” in FIG. 8), to initiate and manage a test process. In other examples, the clock signal can be provided by a different circuit or component of the chip 800, such as an on-chip PLL, as described herein.

For example, the BIST controller 802 generates a test vector command signal (identified as “GEN_TEST” in FIG. 8) to the test pattern generator 804, in response to which the test pattern generator 804 produces one or more test vectors for the functional logic 810 being tested. The chip 800 includes a scan chain circuit 808, which can be the scan chain circuit 122 of FIG. 1 or the scan chain circuit 200 of FIG. 2. An input of the scan chain circuit 808 is coupled to an output of the BIST controller 802 to receive the scan enable signal. Another input of the scan chain circuit 808 is coupled to a second output of the BIST controller 802 to receive the clock signal. A third output of the BIST controller 802 provides the test vector command signal to an input of the test pattern generator 804.

The test pattern generator 804 produces test vectors (e.g., pseudo-random patterns, March algorithms for memory, or deterministic patterns for logic gates) corresponding to a scan data signal (identified as “SCAN_DATA” in FIG. 8) for stimulating the functional logic 810 during a scan mode of operation of the chip 800. These test vectors can be loaded into the scan chain circuit 808 in a manner similar to the ATE-based testing described with respect to FIG. 1. An output of the test pattern generator 804 is coupled to an input of the scan chain circuit 808 to provide the scan data signal. The scan chain circuit 808, including an N number of output-gated scan flip-flop (FF) circuits, as described herein, generates a number of gated data output signals (identified as “Q_OUT1”, “Q_OUT2”, “Q_OUT3” and “Q_OUTN” in FIG. 8) to corresponding inputs of the functional logic 810, where a number of outputs may be less than N depending on a specific design and test requirements of the functional logic 810. Each gated data output signal is generated by corresponding output gating logic of the respective output-gated scan FF circuit within the scan chain circuit 808, based on a stored logic value in a respective data storage circuit and the scan enable signal, as described herein. These signals can be produced during the capture phase when the scan enable signal is de-asserted, reflecting test vector bits loaded during the scan shift phase, synchronized by the clock signal. The scan chain circuit 808 has an input coupled to an output of the functional logic 810 to receive a data result signal (identified as “DATA_OUT” in FIG. 8). The data result signal is generated by the functional logic 810 as a processed response to the gated data output signals during the capture phase and is captured by one or more output scan FF circuits within the scan chain circuit 808 on a clock edge of the clock signal, as described herein.

In some examples, the test response analyzer 806 is coupled to an output of the scan chain circuit 808 to receive a scanned out data signal (identified as “SCAN_OUT” in FIG. 8). The scanned out data signal is derived from the data result signal, which is generated by the functional logic 810 as a processed response to the gated data output signals and captured by one or more output scan FF circuits within the scan chain circuit 808 during the capture phase. A captured data result value represented by the data result signal is stored in a data storage circuit of a respective output scan FF circuit of the scan chain circuit 808 and shifted out as the scanned out data signal during the scan shift phase when the scan enable signal is asserted, synchronized by the clock signal, as described herein. The test response analyzer 806 can be implemented as a standalone component or integrated within the BIST controller 802. The test response analyzer 806 compares one or more logical states represented by the scanned out data signal to one or more expected responses stored in an on-chip memory or generated algorithmically by the test pattern generator 804.

As a non-limiting example, when testing the functional logic 810, such as an arithmetic logic unit (ALU) or memory array in an automotive ECU, the BIST controller 802 can initiate a test during a system idle state, at scheduled intervals, upon initialization, or when the chip 800 receives power. The test pattern generator 804 applies a test vector, such as “101010,” to check for faults (e.g., stuck-at faults in logic gates, timing errors in sequential circuits, or bit flips in memory). The functional logic 810 processes this input and the data result signal is captured by one or more output scan FF circuits within the scan chain circuit 808, which then produce the scanned out data signal during the scan shift phase. The test response analyzer 806 compares the scanned out data signal, such as “101010,” to an expected pattern. In some examples, if a mismatch occurs, such as receiving “101110,” the test response analyzer 806 flags a fault by outputting a fault signal (identified as “FAULT” in FIG. 8), which can be provided to the BIST controller 802 or a system-level controller 812 on the chip 800. The system-level controller 812, which can be implemented as a processor or dedicated control logic, responds to the fault signal by initiating one or more corrective actions, such as logging the fault for diagnostic analysis, switching to a redundant logic block (e.g., a backup ALU or memory bank), resetting the functional logic 810, or commanding the chip 800 to enter a safe mode. A safe mode is a reduced-functionality state in which the chip 800 disables one or more operations (e.g., non-critical operations), restricts outputs to prevent unsafe system behavior and signals an external system (e.g., an automotive control unit) to take over or halt operations, thereby preventing hazardous outcomes in safety-critical applications.

In this description, unless otherwise stated, “about,” “approximately” or “substantially” preceding a parameter means being within +/−10 percent of that parameter. Modifications are possible in the described embodiments and other embodiments are possible within the scope of the claims.

What is claimed is:

1. A flip-flop (FF) circuit comprising:
a data output terminal;
a data selection logic configured to receive a scan enable signal, a scan data input signal and a functional data input signal and to output one of the scan data input signal or the functional data input signal as a selected data signal based on the scan enable signal;
a data storage circuit coupled to the data selection logic and configured to capture and store a logic value represented by the selected data signal as a stored logical value; and
output gating logic coupled to the data output terminal and the data storage circuit and configured to generate a data output signal at the data output terminal based on the stored logical value during a capture phase of a scan mode of operation, wherein, during a scan shift phase of the scan mode of operation, the output gating logic suppresses the data output signal at the data output terminal.

2. The FF circuit of claim 1, wherein during the capture phase of the scan mode, the data output signal provided to the data output terminal corresponds to a stored logical value representing a test vector bit shifted into the data storage circuit during the scan shift phase, the data output signal being applied to a functional logic of the IC device to stimulate the functional logic for testing.

3. The FF circuit of claim 1, wherein the data selection logic comprises:
an AND gate configured to receive the scan enable signal and the scan data input signal and to generate a scan data selection signal when both the scan enable signal and the scan data input signal are at a logical high during the scan shift phase; and
an OR gate configured to receive the scan data selection signal and the functional data input signal and to generate the selected data signal, wherein the selected data signal corresponds to the scan data selection signal when the scan enable signal is at the logical high and to the functional data input signal when the scan enable signal is at a logical low.

4. The FF circuit of claim 3, wherein the AND gate is a first AND gate and the output gating logic comprises:
an inverter configured to generate an inverted scan enable signal of the scan enable signal; and
a second AND gate configured to receive a stored data signal generated by the data storage circuit, the stored data signal being representative of the stored logical value, and the inverted scan enable signal, the second AND gate being further configured to generate the data output signal at the data output terminal when both the stored data signal and the inverted scan enable signal are at a logical high during the capture phase and to suppress the data output signal to a logical low at the data output terminal when the inverted scan enable signal is at a logical low during the scan shift phase.

5. The FF circuit of claim 4, wherein:
the FF circuit is part of a scan chain circuit and further comprises a scan output terminal;
the data storage circuit is configured to provide a scan output signal at the scan output terminal, the scan output signal corresponding to the stored data signal and representing the stored logic value; and
during the scan shift phase the scan output signal is provided to another flip-flop circuit in the scan chain circuit.

6. The FF circuit of claim 1, wherein the data selection logic comprises:
an OR gate configured to receive the scan data input signal and an inverted scan enable signal and to generate a scan data control signal, wherein the scan data control signal is at a logical high when either the scan data input signal is at a logical high or the scan enable signal is at a logical low; and
an AND gate configured to receive the functional data input signal and the scan data control signal and to generate the selected data signal, wherein the selected data signal corresponds to the scan data input signal when the scan enable signal is at a logical high and the functional data input signal is at a logical high, and to the functional data input signal when the scan enable signal is at a logical low.

7. The FF circuit of claim 6, wherein the AND gate is a first AND gate and the output gating logic comprises:
an inverter configured to generate an inverted scan enable signal from the scan enable signal; and
a second AND gate configured to receive a stored data signal generated by the data storage circuit, the stored data signal being representative of the stored logical value, and the inverted scan enable signal, the second AND gate being further configured to generate the data output signal at the data output terminal when both the stored data signal and the inverted scan enable signal are at a logical high during the capture phase and to suppress the data output signal to a logical low at the data output terminal when the inverted scan enable signal is at a logical low during the scan shift phase.

8. The FF circuit of claim 7, wherein:
the FF circuit is part of a scan chain circuit and further comprises a scan output terminal;
the data storage circuit is further configured to provide a scan output signal at the scan output terminal, the scan output signal corresponding to the stored data signal and representing the stored logic value; and
during the scan shift phase the scan output signal is provided to another flip-flop circuit in the scan chain circuit.

9. The FF circuit of claim 1, wherein the data selection logic comprises:
an AND gate configured to receive the scan enable signal and the scan data input signal and to generate a scan data selection signal when both the scan enable signal and the scan data input signal are at a logical high during the scan shift phase; and
an OR gate configured to receive the scan data selection signal and the functional data input signal and to generate the selected data signal, wherein the selected data signal corresponds to the scan data selection signal when the scan enable signal is at the logical high and to the functional data input signal when the scan enable signal is at a logical low.

10. The FF circuit of claim 9, wherein the output gating logic comprises:
a NOR gate configured to receive an inverted output signal from the data storage circuit, the inverted output signal representing a complement of the stored logical value, and the scan enable signal, the NOR gate being further configured to generate the data output signal at the data output terminal as a logical complement of the inverted output signal when the scan enable signal is at a logical low during the capture phase, and to suppress the data output signal to a logical low at the data output terminal when the scan enable signal is at a logical high during the scan shift phase; and
an inverter configured to receive the inverted output signal and to generate a scan output signal representing the stored logical value.

11. The FF circuit of claim 10, wherein:
the FF circuit is part of a scan chain circuit and further comprises a scan output terminal;
the scan output signal is provided at the scan output terminal by the inverter of the output gating logic, the scan output signal representing the stored logical value; and
during the scan shift phase the scan output signal is provided to another flip-flop circuit in the scan chain circuit.

12. The FF circuit of claim 1, wherein the data selection logic comprises:
an inverter configured to generate an inverted scan enable signal from the scan enable signal;
an OR gate configured to receive the inverted scan enable signal and the scan data input signal and to generate a scan data control signal, wherein the scan data control signal is at a logical high when either the scan data input signal is at a logical high or the scan enable signal is at a logical low; and
an AND gate configured to receive the functional data input signal and the scan data control signal and to generate the selected data signal, wherein the selected data signal corresponds to the scan data input signal when the scan enable signal is at a logical high and the functional data input signal is at a logical high, and to the functional data input signal when the scan enable signal is at a logical low.

13. The FF circuit of claim 12, wherein the inverter is a first inverter and the output gating logic comprises:
a NOR gate configured to receive an inverted output signal from the data storage circuit, the inverted output signal representing a complement of the stored logical value, and the scan enable signal, the NOR gate being configured to generate the data output signal at the data output terminal as a logical complement of the inverted output signal when the scan enable signal is at a logical low during the capture phase, and to suppress the data output signal to a logical low at the data output terminal when the scan enable signal is at a logical high during the scan shift phase; and
a second inverter configured to receive the inverted output signal and to generate a scan output signal representing the stored logical value.

14. The FF circuit of claim 13, wherein:
the FF circuit is part of a scan chain circuit and further comprises a scan output terminal;
the scan output signal is provided at the scan output terminal by the second inverter of the output gating logic, the scan output signal representing the stored logical value; and
during the scan shift phase the scan output signal is provided to another flip-flop circuit in the scan chain circuit.

15. The FF circuit of claim 13, wherein:
the FF circuit is part of a scan chain circuit comprising a plurality of FF circuits implemented on an integrated circuit (IC) device;
the IC device comprises functional logic coupled to the scan chain circuit, the functional logic having a plurality of inputs configured to receive data output signals from respective data output terminals of the plurality of FF circuits;
the scan chain circuit is configured to test the functional logic by:
loading test vectors into the plurality of FF circuits during the scan shift phase, wherein the output gating logic of each FF circuit suppresses the data output signal at its respective data output terminal to reduce switching activity in the functional logic;
applying the stored logical values representing the test vectors to the functional logic via data output signals during the capture phase; and
capturing a response from the functional logic and shifting out a scanned out data signal for analysis to verify the functionality of the functional logic.

16. A system comprising:
an integrated circuit (IC) device comprising a scan chain circuit comprising a plurality of flip-flop (FF) circuits, wherein at least one FF circuit comprises:
a data output terminal;
a data selection logic configured to receive a scan enable signal, a scan data input signal and a functional data input signal and to output one of the scan data input signal or the functional data input signal as a selected data signal based on the scan enable signal;
a data storage circuit coupled to the data selection logic and configured to capture and store a logic value represented by the selected data signal as a stored logical value; and
output gating logic coupled to the data output terminal and the data storage circuit and configured to generate a data output signal at the data output terminal based on the stored logical value during a capture phase of a scan mode of operation, wherein, during a scan shift phase of the scan mode of operation, the output gating logic suppresses the data output signal at the data output terminal.

17. The system of claim 16, wherein:
the IC device further comprises functional logic having a plurality of inputs and at least one output, wherein the data output terminal of each of the plurality of FF circuits in the scan chain circuit is coupled to a respective input of the plurality of inputs of the functional logic to provide respective data output signals during the capture phase of the scan mode, the functional logic being configured to process the data output signals to generate a data result signal at the at least one output; and
the scan chain circuit further comprises at least one output scan FF circuit having an input coupled to the at least one output of the functional logic, the at least one output scan FF circuit being configured to capture the data result signal during the capture phase and to provide a scanned out data signal during a subsequent scan shift phase.

18. The system of claim 16, further comprising:
a built-in self-test (BIST) controller configured to generate the scan enable signal and a test vector command signal; and
a test pattern generator configured to generate the scan data input signal in response to the test vector command signal, wherein the scan enable signal and the scan data input signal are provided to the scan chain circuit to control the scan shift phase and the capture phase of the scan mode.

19. The system of claim 16, wherein:
the at least one FF circuit further comprises a scan output terminal coupled to a scan data input terminal of another FF circuit in the scan chain circuit; and
the data storage circuit of the at least one FF circuit is configured to provide a scan output signal at the scan output terminal during the scan shift phase, the scan output signal being generated based on the stored logical value and representing a test vector bit shifted into the data storage circuit.

20. A flip-flop (FF) circuit comprising:
a plurality of terminal comprising a scan data (SD) input terminal, a data output terminal, a scan enable (SE) input terminal and a clock input terminal;
data selection logic having a first input coupled to the SD input terminal, a second input coupled to the SE input terminal and an output;
data storage circuit having a first input coupled to the output of the data selection logic, a second input coupled to the clock input terminal and an output; and
output gating logic having a first input coupled to the output of the data storage circuit, a second input coupled to the SE input terminal and an output coupled to the data output terminal.

21. The FF circuit of claim 20, wherein the plurality of terminal further comprise a SD output terminal, the output gating logic further comprises a second output that is coupled to the SD output terminal.

22. A method for testing an integrated circuit (IC), comprising:
configuring circuitry within the IC to perform scan testing to verify functionality of functional logic or memory elements; and
perform scan testing of at least one of the functional logic and memory elements.

23. The method of claim 22, wherein the scan testing is performed during safety-critical applications while the chip is deployed.

24. The method of claim 22, wherein the scan testing is performed by an Automatic Test Equipment (ATE) prior to the IC being deployed.

25. The method of claim 22, wherein the functional logic may comprise combinational logic or sequential logic.

26. The method of claim 22, wherein the scan testing is performed entirely within the IC by an on-chip built-in self-test (BIST) controller coupled to a test pattern generator and a test response analyzer.

27. The method of claim 22, wherein the scan testing is performed during safety-critical applications while the chip is deployed in a product or apparatus.

28. The method of claim 22, wherein the scan testing is performable by an Automatic Test Equipment (ATE) prior to the IC being deployed and by an on-chip built-in self-test (BIST) controller while the chip is deployed in a product or apparatus.
